(19) United States
(12) Patent Application Publication
(10) Pub. No.: US 2024/0297107 A1
(43) Pub. Date: Sep. 5, 2024

(54) SEMICONDUCTOR DEVICE

(71) Applicant: ROHM CO., LTD., Kyoto-shi (JP)

(72) Inventor: Kohei IKEGAMI, Kyoto-shi (JP)

(21) Appl. No.: 18/663,675

(22) Filed: May 14, 2024

Related U.S. Application Data
(63) Continuation of application No. PCT/JP2022/042025, filed on Nov. 11, 2022.

(30) Foreign Application Priority Data
Nov. 19, 2021 (JP) 2021-188396

(51) Int. Cl. H01L 23/498; H01L 23/00; H01L 23/31

(52) U.S. Cl. CPC H01L 23/49827; H01L 23/3121; H01L 24/16; H01L 2224/16225

(57) ABSTRACT

This semiconductor device comprises: a semiconductor element; a wiring portion to which the semiconductor element is electrically connected; a sealing resin that seals the semiconductor element and the wiring portion; and a pillar electrically connected to the wiring portion and exposed from the back surface of the resin. At least part of the portion of the pillar in contact with the sealing resin has a curved portion that protrudes toward the sealing resin when viewed in the z-direction.

### CROSS-REFERENCE TO RELATED APPLICATIONS

This application is a continuation of, and claims the benefit of priority from International Application No. PCT/JP2022/042025, filed on Nov. 11, 2022, which claims the benefit of priority from Japanese Patent Application No. 2021-188396, filed on Nov. 19, 2021, the entire contents of each of which are incorporated herein by reference.

### BACKGROUND

### 1. Field

The present disclosure relates to a semiconductor device.

### 2. Description of Related Art

Reduction in size of recent electronic apparatuses is promoting reduction in size of a semiconductor device used for the electronic apparatuses. There have been proposals to use a fan-out type semiconductor device, which includes conductors electrically connected to a semiconductor element and extending outward from the semiconductor element (refer to, for example, Japanese Laid-Open Patent Publication No. 2021-93454). A fan-out type semiconductor device is reduced in size and demonstrates increased flexibility in the shape of wiring patterns of a circuit board on which the semiconductor device is mounted.

An example of such a semiconductor device includes an encapsulation resin encapsulating the conductors and the semiconductor element and a thermal pad arranged to overlap the semiconductor element as viewed in the thickness-wise direction of the encapsulation resin. The thermal pad is exposed from a back surface of the encapsulation resin.

### BRIEF DESCRIPTION OF DRAWINGS

FIG. 1 is a schematic plan view showing an encapsulation resin and interconnects in a first embodiment of a semiconductor device.

FIG. 2 is a schematic cross-sectional view of the semiconductor device taken along line F2-F2 in FIG. 1.

FIG. 3 is an enlarged partial view of FIG. 2.

FIG. 4 is a schematic back view of the semiconductor device.

FIG. 5 is a schematic plan view showing the positional relationship of a pillar and an interconnect.

FIG. 6 is a schematic diagram showing an example of a step of manufacturing the semiconductor device of the first embodiment.

FIG. 7 is a schematic diagram showing an example of a step of manufacturing the semiconductor device following the step shown in FIG. 6.

FIG. 8 is a schematic diagram showing an example of a step of manufacturing the semiconductor device following the step shown in FIG. 7.

FIG. 9 is a schematic diagram showing an example of a step of manufacturing the semiconductor device following the step shown in FIG. 8.

FIG. 10 is a schematic diagram showing an example of a step of manufacturing the semiconductor device following the step shown in FIG. 9.

FIG. 11 is a schematic diagram showing an example of a step of manufacturing the semiconductor device following the step shown in FIG. 10.

FIG. 12 is a schematic diagram showing an example of a step of manufacturing the semiconductor device following the step shown in FIG. 11.

FIG. 13 is a schematic diagram showing an example of a step of manufacturing the semiconductor device following the step shown in FIG. 12.

FIG. 14 is a schematic back view showing the positional relationship of an encapsulation resin and bonding layer pieces in a second embodiment of a semiconductor device.

FIG. 15 is a schematic cross-sectional view showing a cross-sectional structure of a portion of the semiconductor device taken along line F15-F15 in FIG. 14.

FIG. 16 is a schematic cross-sectional view showing a cross-sectional structure of the semiconductor device taken along line F16-F16 in FIG. 14.

FIG. 17 is a back view showing a third embodiment of a semiconductor device.

FIG. 18 is a back view showing a modified example of a semiconductor device.

### DETAILED DESCRIPTION

Embodiments of a semiconductor device according to the present disclosure will be described below with reference to the drawings. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

### Structure of Semiconductor Device

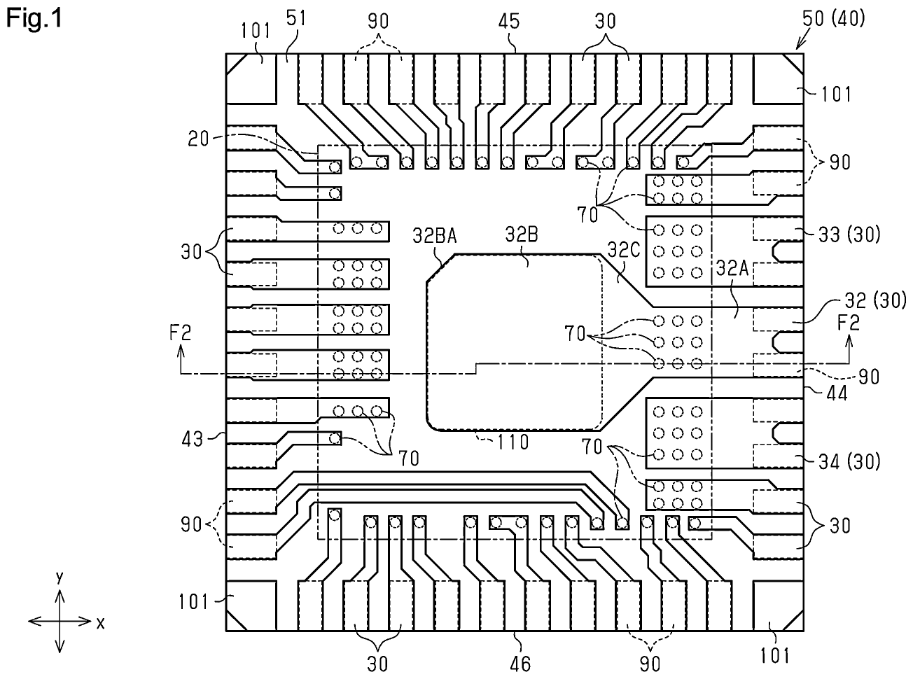

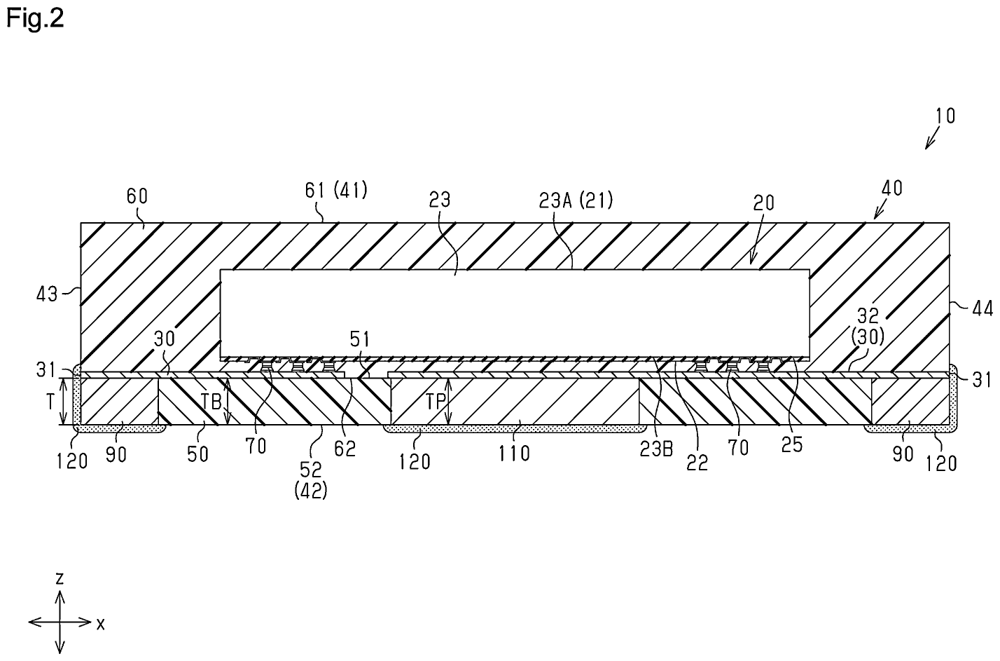

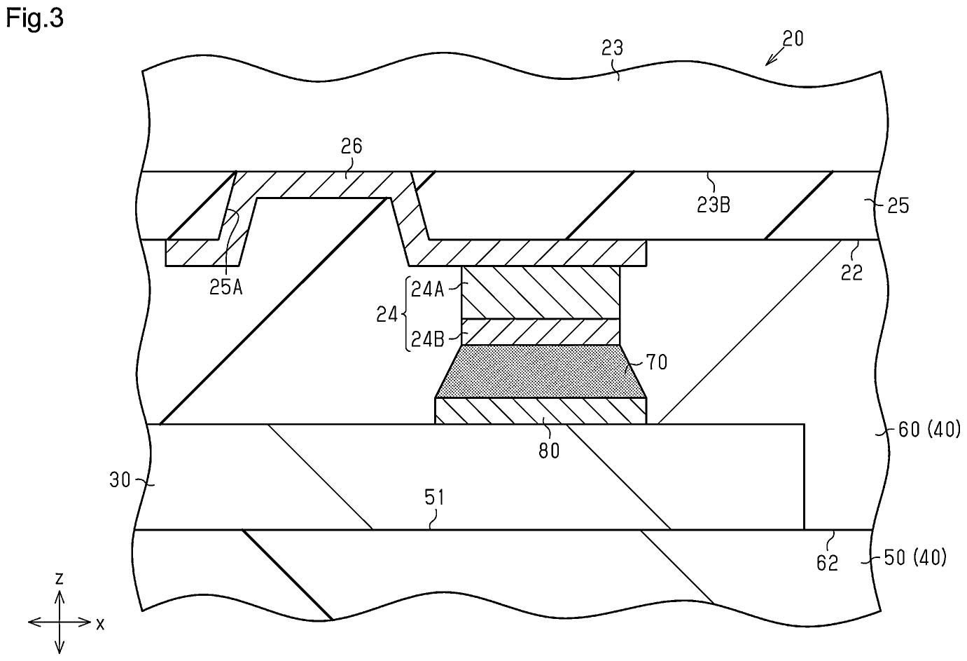

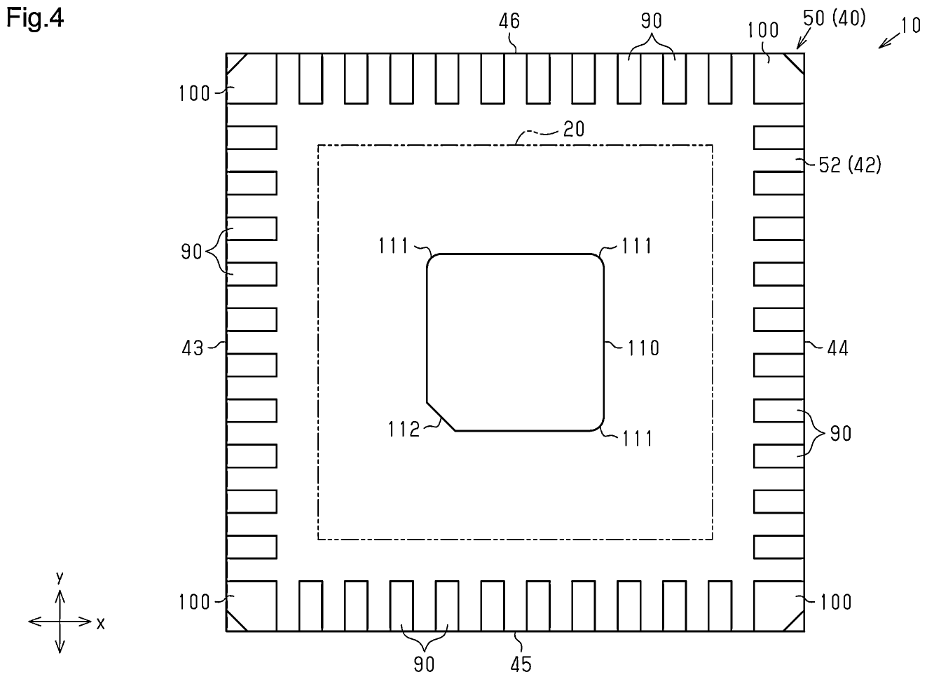

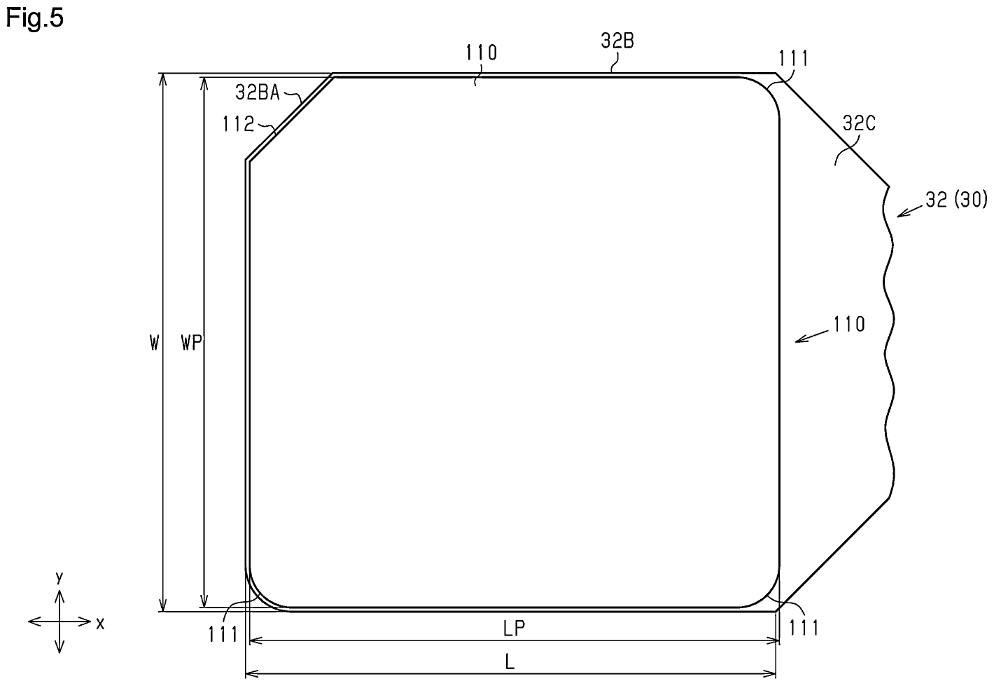

The structure of a first embodiment of a semiconductor device 10 will now be described with reference to FIGS. 1 to 5. In FIG. 1, for the sake of convenience, a semiconductor element 20 and bonding layer pieces 70, which will be described later, are indicated by double-dashed lines. Also, for the sake of convenience, FIG. 1 does not show a portion of an encapsulation resin 40, which will be described later. FIG. 3 is an enlarged view of one of the bonding layer pieces 70 shown in FIG. 2 and its surroundings. In FIG. 5, a pillar 110 is transparently shown and indicated by a solid line to show the positional relationship of the pillar 110 and an interconnect 30, which will be described later. Also, for the sake of convenience, FIGS. 4 and 5 do not show a conductive film 120, which will be described later.

FIGS. 1 and 2, the semiconductor device 10 includes a semiconductor element 20, interconnects 30 electrically connected to the semiconductor element 20, and an encapsulation resin 40 encapsulating the semiconductor element 20 and the interconnects 30. The semiconductor device 10 is configured to be surface-mounted on a circuit board (not shown) of various electronic apparatuses. The semiconductor device 10 has a package structure of a surface mount type.

The encapsulation resin 40 defines an outer surface of the semiconductor device 10. The encapsulation resin 40 is rectangular and flat. Thus, the semiconductor device 10 is rectangular and flat. For the sake of brevity, the thickness-wise direction of the encapsulation resin 40 is referred to as a z-direction. As viewed in the z-direction, a direction along one side of the semiconductor device 10 orthogonal to the z-direction is referred to as an x-direction, and a direction orthogonal to the x-direction and the z-direction is referred to as a y-direction. In the present embodiment, as viewed in the z-direction, the y-direction also extends along one side of the semiconductor device 10.

In the present embodiment, the encapsulation resin 40 is square as viewed in the z-direction. Thus, the semiconductor device 10 is square as viewed in the z-direction. The shape of the encapsulation resin 40 (the shape of the semiconductor device 10) may be changed in any manner. In an example, as viewed in the z-direction, the encapsulation resin 40 (semiconductor device 10) may be rectangular such that the sides in the x-direction are longer than the sides in the y-direction or the sides in the y-direction are longer than the sides in the x-direction.

The encapsulation resin 40 includes a resin front surface 41 and a resin back surface 42 opposite to the resin front surface 41. The encapsulation resin 40 further includes four resin side surfaces joining the resin front surface 41 and the resin back surface 42 in the z-direction, namely, a first resin side surface 43, a second resin side surface 44, a third resin side surface 45, and a fourth resin side surface 46 (refer to FIG. 1).

The encapsulation resin 40 includes a flat substrate part 50 and an encapsulation part 60 formed on the substrate part 50.

The substrate part 50 is a support member used as a base of the semiconductor device 10. The semiconductor element 20 is mounted on the substrate part 50. The substrate part 50 is formed from an insulative material. The substrate part 50 is formed from, for example, a black epoxy resin. The material forming the substrate part 50 may be any insulative material.

The substrate part 50 forms a portion of the encapsulation resin 40 located toward the resin back surface 42. The substrate part 50 includes a substrate front surface 51 facing in the same direction as the resin front surface 41 and a substrate back surface 52 defining the resin back surface 42. The substrate part 50 includes substrate side surfaces defining a portion of the first to fourth resin side surfaces 43 to 46.

The encapsulation part 60 is an encapsulation member that encapsulates the semiconductor element 20. The encapsulation part 60 is formed from an insulative material. The encapsulation part 60 is formed from, for example, a black epoxy resin. The material forming the encapsulation part 60 may be any insulative material.

The substrate part 50 and the encapsulation part 60 may be formed from a material including, for example, a filler that improves heat dissipation properties. In an example, each of the substrate part 50 and the encapsulation part 60 is formed from a black epoxy resin. However, the ratio of a filler contained in the epoxy resin differs between the substrate part 50 and the encapsulation part 60. As a result, an interface is formed in the boundary between the substrate part 50 and the encapsulation part 60.

The encapsulation part 60 forms a portion of the encapsulation resin 40 located toward the resin front surface 41. The encapsulation part 60 includes an encapsulation front surface 61 defining the resin front surface 41 and an encapsulation back surface 62 opposite to the encapsulation front surface 61. The encapsulation back surface 62 is in contact with the substrate front surface 51 of the substrate part 50. The encapsulation back surface 62 of the encapsulation part 60 and the substrate front surface 51 of the substrate part 50 form the interface between the substrate part 50 and the encapsulation part 60. The encapsulation part 60 includes resin side surfaces defining a portion of the first to fourth resin side surfaces 43 to 46.

The substrate part 50 is thinner than the encapsulation part 60. In the present embodiment, the substrate part 50 is thinner than the semiconductor element 20. In an example, the substrate part 50 has a thickness of 40 μm or greater and 70 μm or less. The thickness of the substrate part 50 is defined by the dimension between the substrate front surface 51 and the substrate back surface 52 in the z-direction. The thickness of the encapsulation part 60 is defined by the dimension between the encapsulation front surface 61 and the encapsulation back surface 62 in the z-direction. The thickness of the semiconductor element 20 is defined by the dimension between an element front surface 21 and an element back surface 22 in the z-direction.

The semiconductor element 20 encapsulated in the encapsulation part 60 is, for example, an integrated circuit (IC) such as a large scale integration (LSI). The semiconductor element 20 may be a voltage-controlling element such as a low dropout (LDO) regulator, an amplifying element such as an operational amplifier, or a discrete semiconductor element such as a diode or various sensors.

As shown in FIGS. 1 and 2, the semiconductor element 20 is flat. In the present embodiment, the semiconductor element 20 is square as viewed in the z-direction. The shape of the semiconductor element 20 as viewed in the z-direction may be changed in any manner. In an example, as viewed in the z-direction, the semiconductor element 20 may be rectangular such that the sides in the x-direction are longer than the sides in the y-direction or the sides in the y-direction are longer than the sides in the x-direction.

As shown in FIG. 2, the semiconductor element 20 includes an element front surface 21 and an element back surface 22 opposite to the element front surface 21. The element front surface 21 faces in the same direction as the resin front surface 41. In other words, the resin front surface 41 faces in the same direction as the element front surface 21. The element back surface 22 faces in the same direction as the resin back surface 42. In other words, the element back surface 22 is opposed to the substrate front surface 51 of the substrate part 50. The semiconductor element 20 further includes four element side surfaces joining the element front surface 21 and the element back surface 22 in the z-direction. The semiconductor element 20 is entirely covered by the encapsulation resin 40 (encapsulation part 60).

As shown in FIG. 1, multiple interconnects 30 are arranged. As shown in FIG. 2, the interconnects 30 are formed on the substrate part 50. More specifically, the interconnects 30 are formed on the substrate front surface 51 of the substrate part 50. Since the substrate front surface 51 of the substrate part 50 is a flat surface orthogonal to the z-direction, the interconnects 30 extend in a direction orthogonal to the z-direction.

The interconnects 30 are opposed to the element back surface 22 of the semiconductor element 20. As viewed in the z-direction, each interconnect 30 extends from a position opposed to the element back surface 22 of the semiconductor element 20 to the outside of the semiconductor element 20. In other words, the interconnect 30 includes an extension extending out from the semiconductor element 20 as viewed in the z-direction.

Although not shown, the interconnect 30 includes a metal layer and a main interconnect layer.

The metal layer is formed as a seed layer for forming the main interconnect layer. The metal layer is formed from a material including, for example, titanium (Ti). In the present embodiment, the metal layer includes a Ti layer and a copper (Cu) layer in contact with the Ti layer. The metal layer is formed on the substrate front surface 51 of the substrate part 50. More specifically, the Ti layer is formed on the substrate front surface 51. The Cu layer is formed on the Ti layer. Thus, the metal layer is formed on the substrate front surface 51.

The main interconnect layer is formed on the metal layer. More specifically, the main interconnect layer is formed on the Cu layer of the metal layer. Thus, each interconnect 30 has a stacking structure of the metal layer and the main interconnect layer. The main interconnect layer is formed from, for example, Cu or an alloy including Cu.

As shown in FIG. 1, as viewed in the z-direction, each interconnect 30 extends toward one of the first to fourth resin side surfaces 43 to 46 from a position where the interconnect 30 overlaps the semiconductor element 20. Each interconnect 30 is exposed from the resin side surface corresponding to the interconnect 30. Thus, as shown in FIG. 2, each interconnect 30 includes an exposed interconnect side surface 31 exposed from the resin side surface corresponding to the interconnect 30. In the present embodiment, the exposed interconnect side surface 31 is flush with the resin side surface.

The resin side surface corresponding to the interconnect 30 refers to the resin side surface that is located closest to the interconnect 30. The resin side surface corresponding to the interconnect 30 also refers to the resin side surface on which the exposed interconnect side surface 31 of the interconnect 30 is formed.

FIG. 3 is a diagram showing an example of the structure connecting the semiconductor element 20 and the interconnect 30. As shown in FIG. 3, the semiconductor element 20 includes an element substrate 23, connection terminals 24, an insulation film 25, and a connection wiring line 26. The connection wiring line 26 and the insulation film 25 are arranged on the element substrate 23.

The element substrate 23 is a semiconductor substrate and is formed from a material including, for example, silicon (Si). In the present embodiment, the element substrate 23 is a Si substrate. As shown in FIG. 2, the element substrate 23 includes a front surface 23A and a back surface 23B. The front surface 23A of the element substrate 23 faces the same direction as the element front surface 21 of the semiconductor element 20. The back surface 23B faces in the same direction as the element back surface 22 of the semiconductor element 20. In the present embodiment, the front surface 23A of the element substrate 23 defines the element front surface 21 of the semiconductor element 20. In the present embodiment, the back surface 23B refers to a surface including a functional element (e.g., transistor) of the semiconductor element 20.

As shown in FIG. 3, each connection terminal 24 is located toward the interconnect 30 from the back surface 23B of the element substrate 23. The connection terminal 24 includes a conductor 24A and a barrier layer 24B. The conductor 24A is formed from a material including, for example, Cu. The conductor 24A forms a portion of the connection terminal 24 located toward the element substrate 23. The barrier layer 24B includes, for example, a Ni layer. The barrier layer 24B is formed on the conductor 24A to cover a distal surface of the conductor 24A. The barrier layer 24B limits interfusion of the conductor 24A into the bonding layer piece 70, which will be described later. The structure of the barrier layer 24B may be changed in any manner. In an example, the barrier layer 24B may be formed by stacking a Ni layer, a Pd layer, and a Au layer. In the present embodiment, the connection terminal 24 is cylindrical-rod-shaped. Thus, as viewed in the z-direction, the connection terminal 24 is circular.

The insulation film 25 covers the back surface 23B of the element substrate 23 and exposes the connection terminals 24. The connection wiring line 26 is arranged on the insulation film 25 to connect the element substrate 23 to the connection terminal 24. More specifically, the insulation film 25 includes an opening 25A that exposes the back surface 23B of the element substrate 23. The connection wiring line 26 is arranged in the opening 25A and extends outward from the opening 25A. The connection terminal 24 is arranged on the portion of the connection wiring line 26 extending outward from the opening 25A. Thus, the connection terminal 24 and the opening 25A of the insulation film 25 are arranged at different positions. The connection wiring line 26 electrically connects the element substrate 23 to the connection terminal 24. As shown in FIG. 1, in the z-direction, the interconnects 30 are opposed to the connection terminals 24.

The insulation film 25 is formed from a material including, for example, a polyimide resin. The material forming the insulation film 25 may be changed in any manner. In an example, the insulation film 25 may be formed from a material including a silicon nitride (SiN).

The semiconductor element 20 is connected to the interconnects 30 by the conductive bonding layer pieces 70. The bonding layer pieces 70 are arranged between the semiconductor element 20 and the interconnects 30. The bonding layer pieces 70 electrically connect the semiconductor element 20 to the interconnects 30. The bonding layer pieces 70 are configured to bond the connection terminals 24 of the semiconductor element 20 to the interconnects 30. The bonding layer pieces 70 include a solder layer. The bonding layer pieces 70 are formed of tin (Sn) or an alloy including Sn. The alloy including Sn includes, for example, a tin-silver (Ag)-based alloy and a tin-antimony (Sb)-based alloy. The bonding layer piece 70 is in contact with the barrier layer 24B of the connection terminal 24 of the semiconductor element 20. Thus, the bonding layer piece 70 is bonded to the connection terminal 24.

As shown in FIG. 1, multiple bonding layer pieces 70 may be arranged on a single interconnect 30 or a single bonding layer piece 70 may be arranged on the interconnect 30. The relationship of the interconnect 30 with the number of bonding layer pieces 70 is set, for example, based on the amount of current flowing through the interconnect 30.

As shown in FIG. 3, a protective layer 80 is arranged between the bonding layer piece 70 and the interconnect 30. That is, the semiconductor device 10 includes the protective layer 80 arranged between the interconnect 30 and the bonding layer piece 70. The protective layer 80 is formed from a material including Ni. The protective layer 80 is formed on the interconnect 30. The protective layer 80 is formed on a portion of the interconnect 30 opposed to the connection terminal 24 of the semiconductor element 20 in the z-direction. The thickness of the protective layer 80 (dimension of the protective layer 80 in the z-direction) is, for example, greater than or equal to 3 μm and less than or equal to 5 μm. In the present embodiment, the protective layer 80 is circular as viewed in the z-direction. In the present embodiment, the protective layer 80 is greater in diameter than the connection terminal 24.

The bonding layer piece 70 is formed on the protective layer 80. In the present embodiment, the bonding layer piece 70 is greater in thickness than the protective layer 80. The connection terminal 24 of the semiconductor element 20 is electrically connected to the interconnect 30 by the bonding layer piece 70 and the protective layer 80. Thus, the semiconductor element 20 is mounted on the interconnects 30.

As shown in FIG. 1, the bonding layer piece 70 is circular as viewed in the z-direction. As shown in FIG. 3, since the protective layer 80 is greater in diameter than the connection terminal 24, the bonding layer piece 70 is truncated-cone-shaped.

As shown in FIG. 4, the semiconductor device 10 includes external connection terminals 90 electrically connected to the semiconductor element 20 by the interconnects 30 (refer to FIG. 1). The external connection terminals 90 are arranged on an outermost peripheral portion of the resin back surface 42. Thus, the external connection terminals 90 are located outward from the semiconductor element 20. The external connection terminals 90 are formed from, for example, Cu or an alloy including Cu. The external connection terminals 90 are formed by, for example, electrolytic plating.

In the present embodiment, the external connection terminals 90 are arranged adjacent to the first to fourth resin side surfaces 43 to 46 as viewed in the z-direction. More specifically, multiple external connection terminals 90 are arranged adjacent to the first resin side surface 43. The external connection terminals 90 are separated from each other in a direction extending along the first resin side surface 43 as viewed in the z-direction. Multiple external connection terminals 90 are arranged adjacent to the second resin side surface 44. The external connection terminals 90 are separated from each other in a direction extending along the second resin side surface 44 as viewed in the z-direction. Multiple external connection terminals 90 are arranged adjacent to the third resin side surface 45. The external connection terminals 90 are separated from each other in a direction extending along the third resin side surface 45 as viewed in the z-direction. Multiple external connection terminals 90 are arranged adjacent to the fourth resin side surface 46. The external connection terminals 90 are separated from each other in a direction extending along the fourth resin side surface 46 as viewed in the z-direction. As shown in FIG. 4, the external connection terminals 90 are arranged outward from the semiconductor element 20 as viewed in the z-direction. As described above, the semiconductor device 10 of the present embodiment is of a fan-out type in which the external connection terminals 90 are located outward from the semiconductor element 20.

As viewed in the z-direction, the external connection terminal 90 is rectangular and includes long sides and short sides. The short sides of the external connection terminal 90 extend in an arrangement direction of the external connection terminals 90. The long sides extend in a direction orthogonal to the arrangement direction as viewed in the z-direction.

As shown in FIGS. 2 and 4, the external connection terminals 90 are exposed from the resin back surface 42 and one of the first to fourth resin side surfaces 43 to 46. More specifically, as viewed in the z-direction, the external connection terminals 90 located adjacent to the first resin side surface 43 are exposed from the resin back surface 42 and the first resin side surface 43. As viewed in the z-direction, the external connection terminals 90 located adjacent to the second resin side surface 44 are exposed from the resin back surface 42 and the second resin side surface 44. As viewed in the z-direction, the external connection terminals 90 located adjacent to the third resin side surface 45 are exposed from the resin back surface 42 and the third resin side surface 45. As viewed in the z-direction, the external connection terminals 90 located adjacent to the fourth resin side surface 46 are exposed from the resin back surface 42 and the fourth resin side surface 46.

As shown in FIG. 2, the external connection terminals 90 are connected to the interconnects 30. The external connection terminals 90 are arranged on the substrate part 50 and extend from the interconnects 30 toward the resin back surface 42. The external connection terminals 90 extend through the substrate part 50 in the z-direction. The external connection terminals 90 are covered by the interconnects 30 in the z-direction and thus do not project from the substrate front surface 51 of the substrate part 50 toward the resin front surface 41. Also, the external connection terminals 90 do not project from the substrate back surface 52 (resin back surface 42) of the substrate part 50 in a direction opposite to the substrate front surface 51. Thus, a thickness T of the external connection terminal 90 is equal to a thickness TB of the substrate part 50.

As shown in FIG. 4, the resin back surface 42 includes four corners, each of which includes a corner terminal 100. The corner terminal 100 and the external connection terminal 90 are formed from the same material. The corner terminal 100 is exposed from the resin back surface 42 and two resin side surfaces forming the corner. In the present embodiment, the corner terminal 100 is electrically disconnected from the interconnects 30. The corner terminal 100 extends through the substrate part 50 in the z-direction. Thus, the corner terminal 100 has a thickness that is equal to the thickness T of the external connection terminal 90.

As shown in FIG. 1, as viewed in the z-direction, a corner interconnect 101 is arranged on the substrate front surface 51 of the substrate part 50 to overlap the corner terminal 100 (refer to FIG. 4). The corner interconnect 101, which differs from the interconnect 30, is electrically disconnected from the semiconductor element 20. The corner interconnect 101 and the interconnect 30 are formed from, for example, the same material. In the same manner as the interconnect 30, the corner interconnect 101 may have a stacking structure of a metal layer and a main interconnect layer.

As shown in FIG. 2, the semiconductor device 10 includes a pillar 110 exposed from the resin back surface 42. As viewed in the z-direction, the pillar 110 is arranged to overlap the semiconductor element 20. As shown in FIG. 4, in the present embodiment, the pillar 110 is arranged in the center of the resin back surface 42. The pillar 110 and the external connection terminals 90 are formed from the same material. The pillar 110 is a thermal pad that releases heat from the semiconductor element 20 to the outside of the encapsulation resin 40.

As shown in FIG. 2, the pillar 110 extends through the substrate part 50. The pillar 110 is covered by the interconnect 30 in the z-direction and thus does not project from the substrate front surface 51 of the substrate part 50 toward the resin front surface 41. Also, the pillar 110 does not project from the substrate back surface 52 (resin back surface 42) of the substrate part 50 in a direction opposite to the substrate front surface 51. Thus, the pillar 110 has a thickness TP that is equal to the thickness TB of the substrate part 50. In other words, the thickness TP of the pillar 110 is equal to the thickness T of the external connection terminal 90.

The interconnects 30 include an interconnect 32 extending from the second resin side surface 44 to the center of the resin back surface 42. The pillar 110 is connected to the interconnect 32. Thus, the pillar 110 is electrically connected to the interconnect 32. As shown in FIG. 1, the interconnect 32 is wider than the other interconnects 30. The interconnect 32 may be divided into an outer part 32A located toward the second resin side surface 44, an inner part 32B located toward the center of the substrate front surface 51, and a joining part 32C that joins the outer part 32A and the inner part 32B.

The outer part 32A extends from the second resin side surface 44 toward the center of the substrate front surface 51 in the x-direction. As viewed in the z-direction, the outer part 32A may be divided into a first section overlapping the semiconductor element 20 and a second section extending from the first section beyond the semiconductor element 20. The second section is connected to two external connection terminals 90. The outer part 32A is equal in width-wise dimension to interconnects 33 and 34, which are located adjacent to the outer part 32A in the y-direction. The interconnects 33 and 34 are greater in width-wise dimension than the interconnects 30 excluding the interconnects 32 to 34. Each of the interconnects 32 to 34 is connected to two of the external connection terminals 90. A greater number of bonding layer pieces 70 is arranged on each of the interconnects 32 to 34 than on the other interconnects 30. The interconnects 30 excluding the interconnects 32 to 34 are each connected to one external connection terminal 90.

The inner part 32B is greater in width-wise dimension than the outer part 32A. As viewed in the x-direction, the inner part 32B partially overlaps the interconnects 33 and 34. Among four corners of the inner part 32B, the corner located toward the first resin side surface 43 and the third resin side surface 45 includes a chamfered slope 32BA.

The joining part 32C is arranged between the outer part 32A and the inner part 32B in the x-direction. The joining part 32C is tapered so that the width increases from the outer part 32A toward the inner part 32B.

As shown in FIG. 5, as viewed in the z-direction, the pillar 110 overlaps the inner part 32B. The pillar 110 is connected to the inner part 32B. In the present embodiment, the pillar 110 has a width-wise dimension WP that is slightly smaller than a width-wise dimension W of the inner part 32B. The pillar 110 has a length LP in the x-direction that is equal to a length L of the inner part 32B in the x-direction. The width-wise dimension WP of the pillar 110 is larger than the width-wise dimension of the outer part 32A (refer to FIG. 1). As shown in FIG. 4, the width-wise dimension WP of the pillar 110 (refer to FIG. 5) is larger than a width-wise dimension of the external connection terminal 90 (short side of the external connection terminal 90). In the present embodiment, the width-wise dimension WP of the pillar 110 is larger than the long side of the external connection terminal 90. The length LP (refer to FIG. 5) of the pillar 110 is greater than the long side of the external connection terminal 90.

As shown in FIG. 1, the bonding layer pieces 70 are arranged on the outer part 32A, whereas the pillar 110 is arranged on the inner part 32B. Thus, the bonding layer pieces 70 and the pillar 110, each of which overlaps with the interconnect 32 in the z-direction, do not overlap with each other in the z-direction. More specifically, the bonding layer pieces 70 are arranged between the pillar 110 and the external connection terminals 90 connected to the interconnect 32 in the x-direction.

As shown in FIG. 5, as viewed in the z-direction, the pillar 110 is quadrilateral (rectangular). The pillar 110 includes a curved portion 111 that relieves stress from the encapsulation resin 40. The curved portion 111 is formed on at least a part of the portion of the pillar 110 contacting the encapsulation resin 40. In the present embodiment, the curved portion 111 is arranged on three of the four corners of the pillar 110. Thus, the pillar 110 is shaped as a polygon including corners that are rounded as the curved portions 111 as viewed in the z-direction. In the present embodiment, the pillar 110 is shaped as a quadrilateral including three corners that are rounded as the curved portions 111 as viewed in the z-direction. In an example, the curved portion 111 is arc-shaped. In the present embodiment, the curved portion 111 is quadrantal. The radius of the curved portion 111 is, for example, greater than or equal to the largest diameter of the bonding layer pieces 70 (refer to FIG. 1). As described above, the curved portion 111 is convex toward the encapsulation resin 40 as viewed in the z-direction.

As viewed in the z-direction, each curved portion 111 is arranged to overlap the interconnect 32 (inner part 32B). In other words, the interconnect 32 includes a portion overlapping the curved portion 111 as viewed in the z-direction. As viewed in the z-direction, the interconnect 32 (inner part 32B) includes a portion extending out from the curved portion 111.

Among the four corners of the pillar 110, the corner that does not include the curved portion 111 includes a chamfered slope 112. The slope 112 is arranged on one of the four corners of the pillar 110 that is located toward the first resin side surface 43 and the third resin side surface 45. Thus, as viewed in the z-direction, the slope 112 is arranged at a position corresponding to the slope 32BA of the interconnect 32.

As shown in FIG. 2, the conductive films 120 are arranged on portions of the external connection terminals 90 exposed from the encapsulation resin 40. The conductive films 120 cover the exposed interconnect side surfaces 31 of the interconnects 30 in addition to the external connection terminals 90. In addition, a conductive film 120 is arranged on a portion of the pillar 110 exposed from the resin back surface 42. The conductive films 120 are formed by, for example, electroless plating. Further, although not shown in the drawings, a conductive film 120 is arranged on a portion of the corner terminal 100 exposed from the encapsulation resin 40.

### Semiconductor Device Manufacturing Method

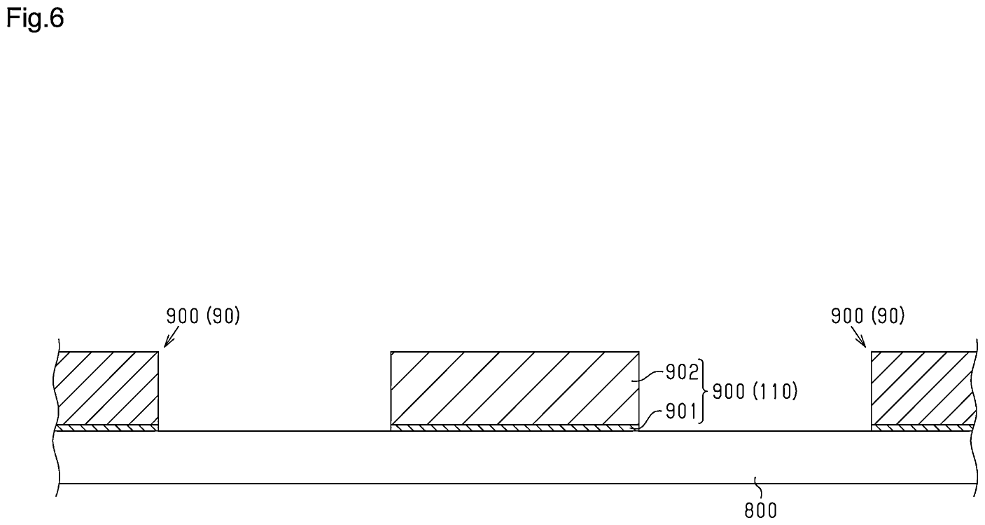

An example of a method for manufacturing the semiconductor device 10 will now be described with reference to FIGS. 6 to 13.

As shown in FIG. 6, in the method for manufacturing the semiconductor device 10, for example, metal pillars 900 are formed on a semiconductor wafer 800 that is formed from a monocrystalline Si material.

The metal pillars 900 include the external connection terminals 90, the corner terminals 100 (refer to FIG. 4), and the pillar 110. That is, the external connection terminals 90, the corner terminals 100, and the pillar 110 are formed simultaneously. The metal pillars 900 are greater in thickness than the external connection terminals 90, the corner terminals 100, and the pillar 110.

The metal pillars 900 are formed by, for example, electrolytic plating. More specifically, a seed layer 901 is formed on the semiconductor wafer 800. Then, the seed layer 901 undergoes photolithography to form a mask (not shown). The mask is removed after a plating metal 902 is formed in contact with the seed layer 901. Thus, each metal pillar 900 has a stacking structure of the seed layer 901 and the plating metal 902.

The seed layer 901 is formed on the semiconductor wafer 800 by, for example, sputtering. Next, for example, the seed layer 901 is covered by a photosensitive resist layer, and the resist layer undergoes reaction with light and development to form a mask having openings. Electrolytic plating in which the seed layer 901 is used as a conductive path is performed so that plating metal 902 deposits on the surface of the seed layer 901 exposed from the mask. The steps described above form the metal pillars 900. Subsequent to formation of the metal pillars 900, the mask is removed.

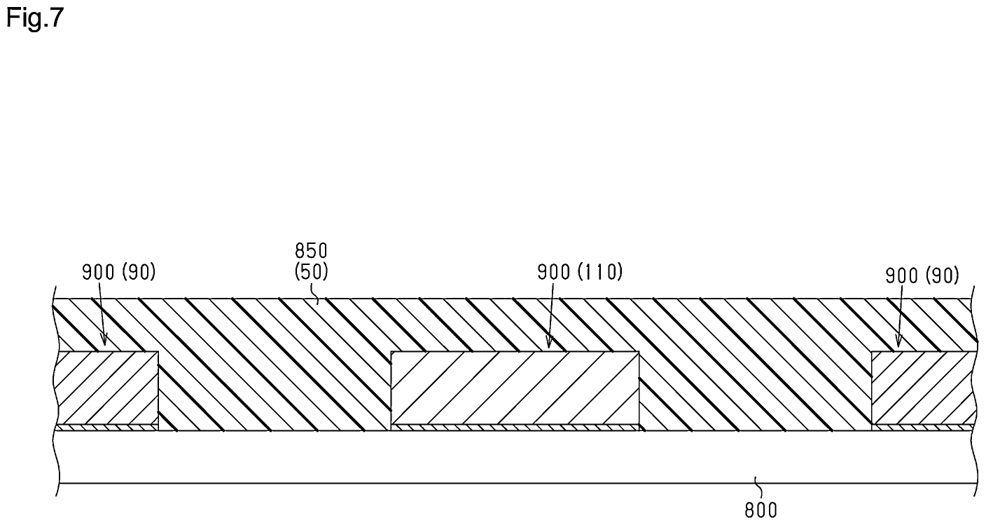

As shown in FIG. 7, in the manufacturing method of the semiconductor device 10, a substrate layer 850 is formed on the semiconductor wafer 800. The substrate layer 850 is a resin layer that forms the substrate part 50 of the semiconductor device 10 and encapsulates the metal pillars 900 between the substrate layer 850 and the semiconductor wafer 800. The substrate layer 850 is formed from, for example, a black epoxy resin. The substrate layer 850 shown in FIG. 7 is greater in thickness than the substrate part 50.

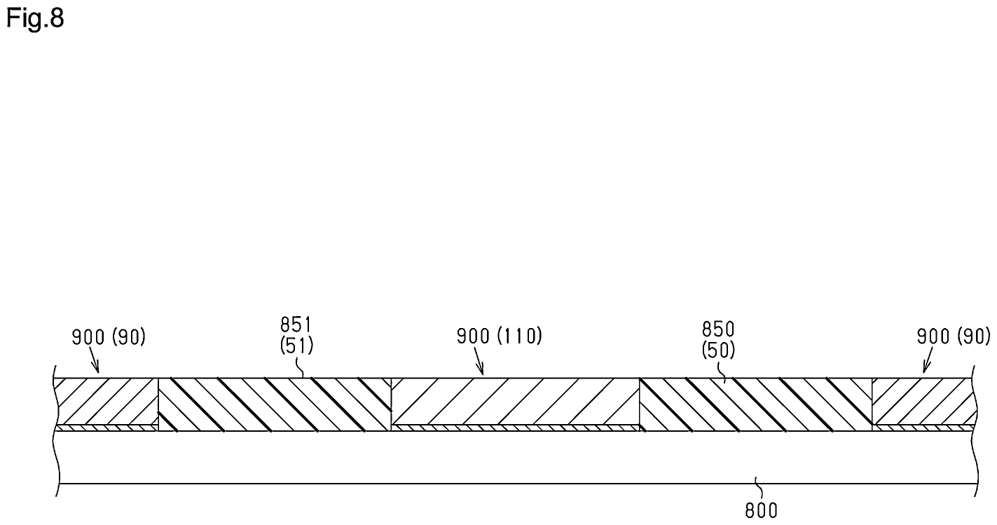

As shown in FIG. 8, in the manufacturing method of the semiconductor device 10, the substrate layer 850 and the metal pillars 900 are ground. In the thickness-wise direction of the substrate layer 850, the substrate layer 850 and the metal pillars 900 are ground from the side opposite to the semiconductor wafer 800. As a result, in the thickness-wise direction of the substrate layer 850, the metal pillars 900 are exposed from the substrate layer 850. In this step, it is preferred that the thickness of the substrate layer 850 is less than or equal to 90 μm.

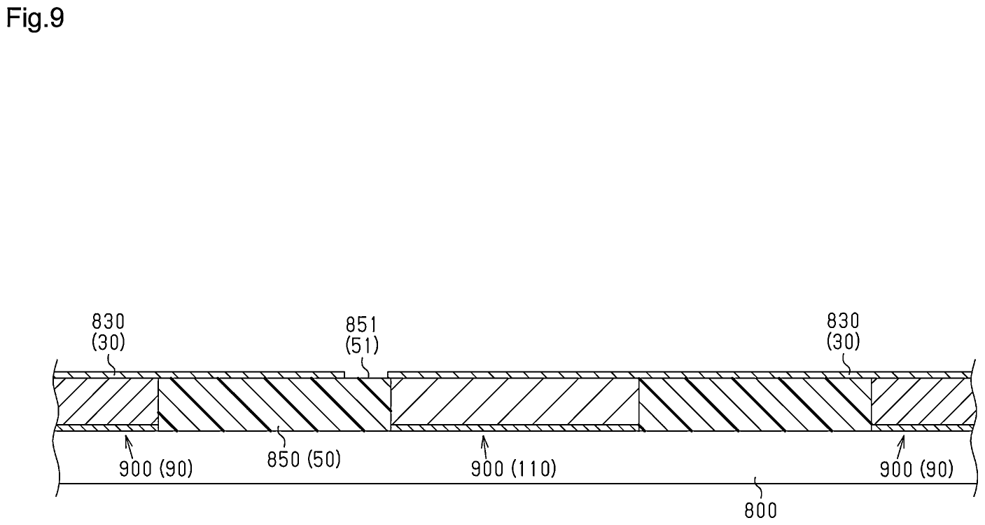

As shown in FIG. 9, in the manufacturing method of the semiconductor device 10, an interconnect layer 830 is formed. The interconnect layer 830 is a metal layer that forms the interconnects 30 and the corner interconnects 101 (refer to FIG. 1) of the semiconductor device 10 and is formed on a surface 851 of the substrate layer 850 and the metal pillars 900 that have been ground. The surface 851 of the substrate layer 850 defines the substrate front surface 51 of the substrate part 50.

The interconnect layer 830 includes a metal layer and a main interconnect layer.

The metal layer is formed by, for example, sputtering on the surface 851 of the substrate layer 850 and a portion of the metal pillars 900 that have been ground. The metal layer includes, for example, a Ti layer and a Cu layer. In an example of a specific formation process, the Ti layer is formed on the surface 851 of the substrate layer 850 and a portion of the metal pillars 900. The Cu layer is formed in contact with the Ti layer.

The metal layer undergoes photolithography to form a mask. In an example of a specific formation process, the metal layer is covered by a photosensitive resist layer, and the resist layer undergoes exposure and development to form a mask having openings. The openings in the mask correspond to positions where the interconnects 30 and the corner interconnects 101 (refer to FIG. 4) are formed.

In an example, the main interconnect layer is formed by electrolytic plating in which the metal layer is used as a conductive path so that plating metal deposits on the surface of the metal layer exposed from the openings of the mask. Subsequently, the mask is removed.

Then, the portion of the metal layer that does not overlap the main interconnect layer is removed. In an example, the main interconnect layer and the metal layer undergo photolithography to form a mask. Then, openings are formed in the portion of the metal layer that does not overlap the main interconnect layer. The metal layer exposed from the openings of the mask is removed. Subsequently, the mask is removed. The steps described above form the interconnect layer 830, which forms the interconnects 30 and the corner interconnects 101.

Since the substrate layer 850 and the metal pillars 900 are reduced in thickness prior to formation of the interconnect layer 830, warpage of the semiconductor wafer 800 is limited after formation of the interconnect layer 830. Thus, the semiconductor wafer 800 is readily transported in a step subsequent to formation of the interconnect layer 830.

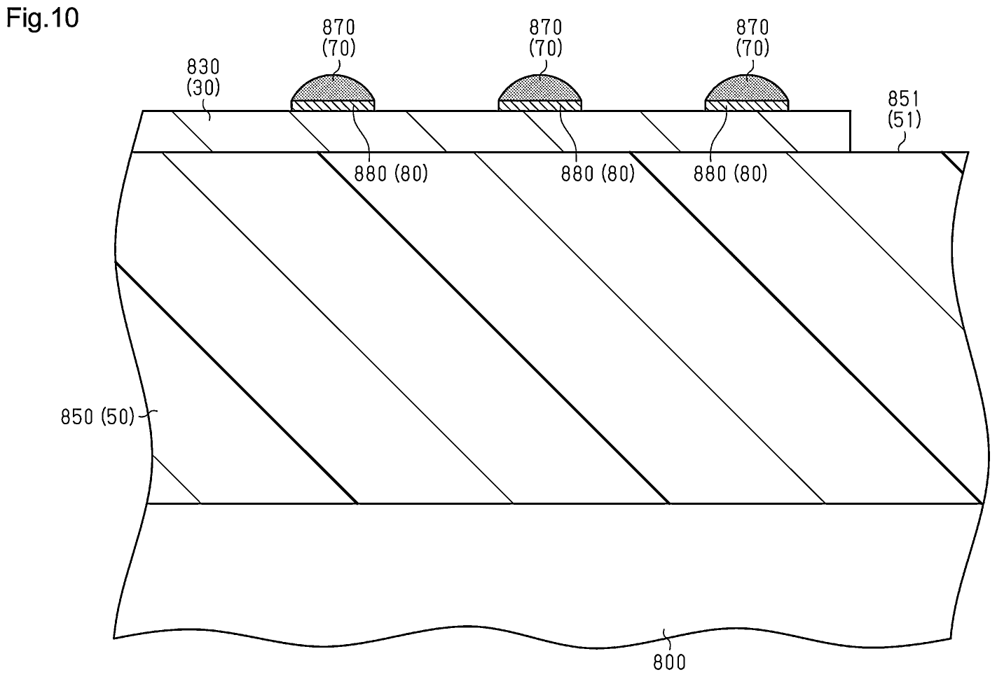

As shown in FIG. 10, in the manufacturing method of the semiconductor device 10, a protective layer 880 and a bonding layer 870 are formed. The protective layer 880 is formed by, for example, electrolytic plating in which the interconnect layer 830 is used as a conductive path. The protective layer 880 is formed from, for example, Ni. As viewed in the thickness-wise direction of the substrate layer 850, the protective layer 880 is circular.

Then, the electrolytic plating is performed so that an alloy including Sn deposits on the protective layer 880 as plating metal. This forms the bonding layer 870. Subsequently, a reflow process is performed to melt the bonding layer 870, thereby smoothing the rough surface of the bonding layer 870. The smoothing limits formation of voids when the bonding layer 870 is bonded to a solder layer of the semiconductor element 20. FIG. 10 shows a state of the bonding layer 870 that has undergone the reflow process. As viewed in the thickness-wise direction of the substrate layer 850, the bonding layer 870 is circular.

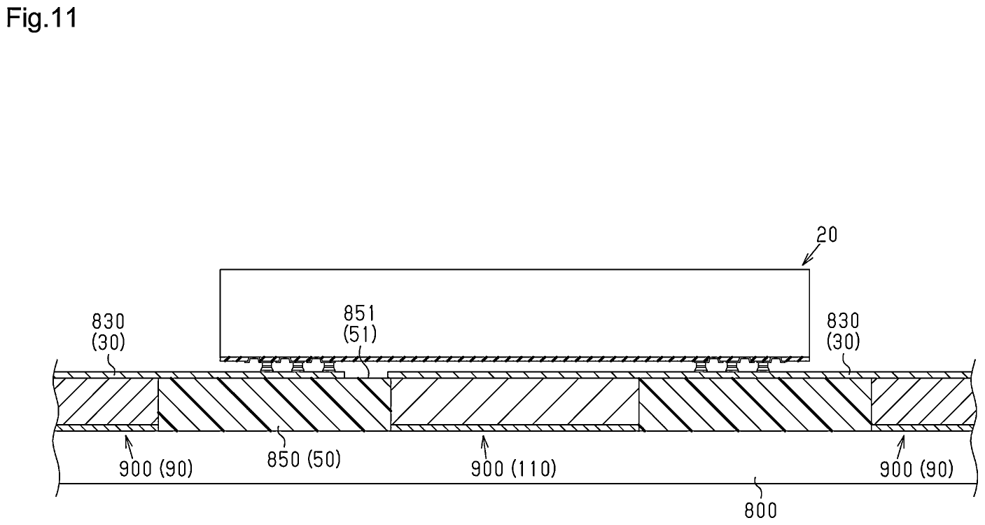

As shown in FIG. 11, in the manufacturing method of the semiconductor device 10, the semiconductor element 20 is mounted on the interconnect layer 830. The semiconductor element 20 is mounted by flip chip bonding (FCB).

In the mounting of the semiconductor element 20, for example, electrolytic planting is performed so that an alloy including Sn deposits as plating metal on the barrier layer 24B (refer to FIG. 3) of the connection terminals 24 of the semiconductor element 20 to form a solder layer (not shown). The solder layer is formed from, for example, the same material as that forming the bonding layer 870 (refer to FIG. 10). In the same manner as the bonding layer 870, the reflow process is performed to smooth the surface of the solder layer of the semiconductor element 20. As viewed in the thickness-wise direction of the substrate layer 850, the solder layer is circular.

For example, a flux is applied to the solder layer of the semiconductor element 20, and then the semiconductor element 20 is mounted on the bonding layer 870 using, for example, a flip-chip bonder. Thus, the semiconductor element 20 is temporarily attached to the bonding layer 870. Subsequently, the reflow process is performed so that the bonding layer 870 and the solder layer of the semiconductor element 20 change the phase to a liquid state, and then the bonding layer 870 and the solder layer of the semiconductor element 20 are cooled and solidified. As a result, the semiconductor element 20 is bonded to the bonding layer 870. Thus, the bonding layer piece 70 (refer to FIG. 3) is formed of the bonding layer 870 and the solder layer of the semiconductor element 20. The bonding layer piece 70 is truncated-cone-shaped.

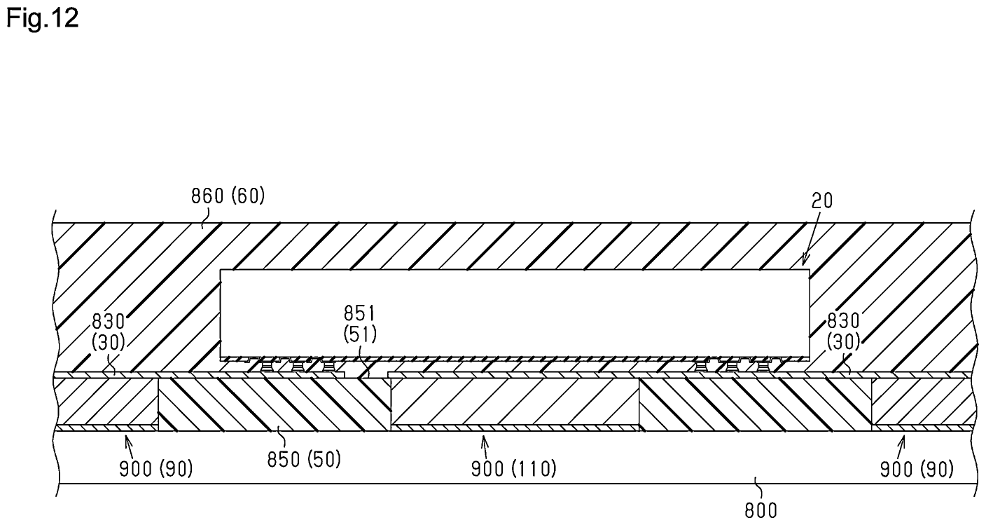

As shown in FIG. 12, in the manufacturing method of the semiconductor device 10, an encapsulation layer 860 that encapsulates the semiconductor element 20 is formed. The encapsulation layer 860 forms the encapsulation part 60 (refer to FIG. 2) of the encapsulation resin 40. The encapsulation layer 860 is formed from, for example, a black epoxy resin. The encapsulation resin 40 is formed of the substrate layer 850 and the encapsulation layer 860. The encapsulation layer 860 is formed by, for example, compression molding.

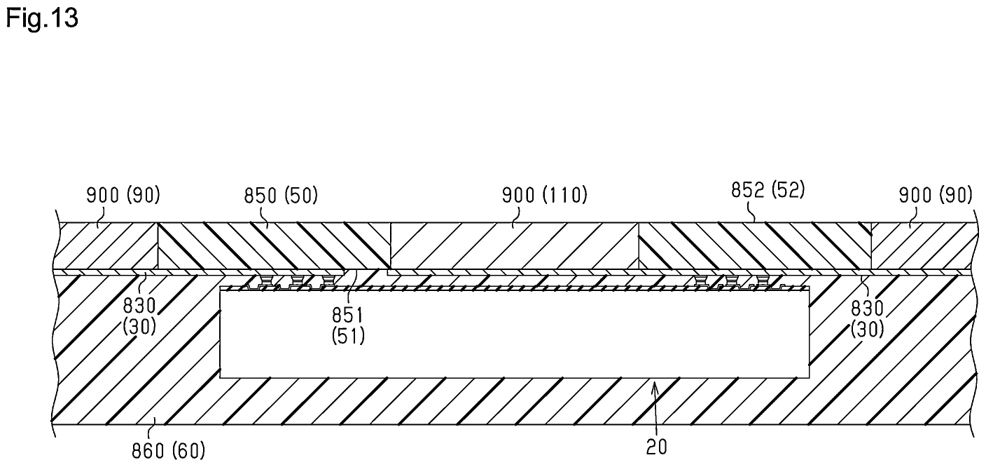

As shown in FIG. 13, in the manufacturing method of the semiconductor device 10, the semiconductor wafer 800 (refer to FIG. 12) is removed. The upper and lower sides in FIG. 12 are reversed in FIG. 13.

The semiconductor wafer 800 is removed from the substrate layer 850 by, for example, grinding. When the semiconductor wafer 800 is removed from the substrate layer 850, the substrate layer 850 and the metal pillars 900 are partially removed in the thickness-wise direction of the substrate layer 850. As a result, the seed layer 901 (refer to FIG. 6) is removed from the metal pillars 900. Also, as a result of removal of the semiconductor wafer 800 from the substrate layer 850, the metal pillars 900 are exposed from the substrate layer 850 at the side opposite from the encapsulation layer 860. The substrate layer 850 includes a back surface 852 defining the substrate back surface 52 of the substrate part 50.

In this step, the thickness of the substrate layer 850 becomes equal to the thickness of the substrate part 50. The thickness of the metal pillars 900 becomes equal to the thickness of each of the external connection terminals 90, the corner terminals 100 (refer to FIG. 4), and the pillar 110. In an example, the thickness of the substrate layer 850 is greater than or equal to 40 μm and less than or equal to 70 μm.

The means of removing the semiconductor wafer 800 may be changed in any manner. In an example, in the step of removing the semiconductor wafer 800, a separation film may be formed in advance, and the semiconductor wafer 800 may be removed by separation. Subsequent to separation of the semiconductor wafer 800, the substrate layer 850 and the metal pillars 900 may be ground.

Subsequently, in the manufacturing method of the semiconductor device 10, a step of cutting the substrate layer 850 and the encapsulation layer 860 for singulation and a step of forming a conductive film are performed. When the substrate layer 850 and the encapsulation layer 860 are cut, the side surface of the metal pillar 900 is exposed from the substrate layer 850, and the side surface of the interconnect layer 830 is exposed from the encapsulation layer 860. The conductive film is formed on the surface of the metal pillar 900 and the side surface of the interconnect layer 830 exposed from the substrate layer 850 and the encapsulation layer 860. The conductive film is formed by, for example, electroless plating. The steps described above manufacture the semiconductor device 10.

### Operation

The operation of the semiconductor device 10 of the present embodiment will be described.

Changes in the temperature of the semiconductor device 10 produce stress is in the substrate part 50 due to the difference between the thermal expansion coefficient of the substrate part 50 and the thermal expansion coefficient of the pillar 110 and the external connection terminals 90. As the temperature of the semiconductor device 10 changes, the pillar 110, having a greater volume than the external connection terminal 90, expands and contracts by a greater amount than the external connection terminal 90. Hence, cracks are likely to be formed in the substrate part 50 located adjacent to the pillar 110. The inventor of this application found from test results and the like that when the pillar 110 includes a non-chamfered corner, stress is increased in the substrate part 50 located adjacent to the pillar 110. As a result, cracks are more likely to be formed in the substrate part 50. Cracks are formed in the substrate part 50 from the substrate back surface 52 toward the substrate front surface 51. That is, the cracks extend in the thickness-wise direction of the substrate part 50. If the cracks extend to the interconnects 30, the interconnects 30 may contact an object (e.g., moisture) present outside the semiconductor device 10.

In this regard, the thickness of the substrate part 50 may be increased to hinder the cracks from extending to the interconnects 30. This improves the strength of the substrate part 50. Thus, cracks are less likely to be formed.

However, in the manufacturing method of the semiconductor device 10, if the interconnect layer 830 is formed on the substrate layer 850 having a large thickness, the semiconductor wafer 800 may be warped. This hampers transportation of the semiconductor wafer 800 in the next step. Hence, in the manufacturing method of the semiconductor device 10, subsequent to formation of the substrate layer 850, the substrate layer 850 and the metal pillars 900 are cut to decrease the thickness of the substrate layer 850 and the thickness of the metal pillars 900. When the semiconductor wafer 800 is removed from the substrate layer 850, the substrate layer 850 is partially cut to ensure that the metal pillars 900 are exposed from the substrate layer 850. The thickness of the substrate layer 850 that has been cut is equal to the thickness of the substrate part 50 of the semiconductor device 10. The metal pillars 900 form the pillar 110 and the external connection terminals 90.

Hence, it is difficult to excessively increase the thickness of the substrate part 50. When the thickness of the substrate part 50 is decreased, the strength of the substrate part 50 is decreased. As a result, cracks are likely to be formed due to stress produced in the substrate part 50.

In this regard, in the present embodiment, the curved portions 111 are arranged in the corners of the pillar 110. Thus, even when the temperature of the semiconductor device 10 changes, stress applied to the substrate part 50 adjacent to the pillar 110 is decreased. As a result, cracks are less likely to be formed in the substrate part 50.

Changes in the temperature of the semiconductor device 10 produce stress in the bonding layer piece 70 due to the difference between the thermal expansion coefficient of the bonding layer piece 70 and the thermal expansion coefficient of the encapsulation part 60. The inventor of this application found from test results and the like that when the bonding layer piece 70 has a corner that is not chamfered as viewed in the z-direction, stress produced in the bonding layer piece 70 is increased. As a result, cracks are more likely to be formed in the bonding layer piece 70.

In this regard, in the present embodiment, the bonding layer piece 70 is arranged so that the bonding layer piece 70 is circular as viewed in the z-direction. Thus, even when the temperature of the semiconductor device 10 changes, stress applied to the bonding layer piece 70 is decreased. As a result, cracks are less likely to be formed in the bonding layer piece 70.

### Advantages

The semiconductor device 10 of the present embodiment has the following advantages.
(1-1) The semiconductor device 10 includes the semiconductor element 20 including the element front surface 21 and the element back surface 22, the interconnects 30 electrically connected to the semiconductor element 20, the encapsulation resin 40, and the pillar 110. The encapsulation resin 40 includes the resin front surface 41 facing in the same direction as the element front surface 21, the resin back surface 42 opposite to the resin front surface 41, and the resin side surfaces, namely, the first to fourth resin side surfaces 43 to 46, and encapsulates the semiconductor element 20 and the interconnects 30. The pillar 110 is electrically connected to the interconnects 30 and is exposed from the resin back surface 42. The pillar 110 includes a portion contacting the encapsulation resin 40 and at least partially including the curved portions 111 being convex toward the encapsulation resin 40 as viewed in the z-direction.

In this structure, the curved portions 111 relieve stress applied from the encapsulation resin 40 to the pillar 110. Accordingly, stress (reaction force) applied from the pillar 110 to the encapsulation resin 40 is decreased. Thus, even when the temperature of the semiconductor device 10 is changed, cracks caused by the pillar 110 are less likely to be formed in the encapsulation resin 40.
(1-2) The pillar 110 is shaped as a polygon (quadrilateral) including a corner that is rounded as the curved portion 111 as viewed in the thickness-wise direction (z-direction) of the encapsulation resin 40.

As described above in the operation of the present embodiment, stress is likely to be produced in the encapsulation resin 40 located adjacent to a corner of the pillar 110. The corners of the pillar 110 are rounded to decrease the stress applied from the pillar 110 to the encapsulation resin 40.
(1-3) As viewed in the thickness-wise direction (z-direction) of the encapsulation resin 40, the interconnect 32 (30) includes a portion overlapping the curved portion 111. As viewed in the z-direction, the interconnect 32 includes the extension extending out from the curved portion 111.

When the encapsulation resin 40 is surrounded by the interconnect 32 and the pillar 110, stress applied from the pillar 110 to the encapsulation resin 40 is likely to be increased. In the present embodiment, the pillar 110 includes the curved portions 111 so that stress applied from the pillar 110 to the encapsulation resin 40 is decreased. Therefore, even when the encapsulation resin 40 includes a portion surrounded by the interconnect 32 and the pillar 110, cracks are less likely to be formed in the encapsulation resin 40.
(1-4) The pillar 110 is a thermal pad.

In this structure, heat is released from the semiconductor element 20 to the outside of the semiconductor device 10 through the pillar 110.
(1-5) The external connection terminals 90 are each exposed from the resin back surface 42 and one of the first to fourth resin side surfaces 43 to 46 of the encapsulation resin 40. The semiconductor device 10 includes the conductive film 120 covering a portion of each external connection terminal 90 exposed from the encapsulation resin 40.

In this structure, when the semiconductor device 10 is mounted on a circuit board, for example, using solder, the solder adheres to a portion of each external connection terminal 90 exposed from one of the first to fourth resin side surfaces 43 to 46. Thus, the mount state of the semiconductor device 10 on the circuit board with the solder is visually recognized. This facilitates the checking of the mount state of the semiconductor device 10 on the circuit board.
(1-6) The semiconductor device 10 includes the conductive film 120 covering a portion of the pillar 110 exposed from the resin back surface 42.

In this structure, when the semiconductor device 10 is mounted on the circuit board, the pillar 110 is bonded to the circuit board by the conductive film 120. Thus, heat is readily transferred from the semiconductor element 20 to the circuit board through the pillar 110 and the conductive film 120.
(1-7) The semiconductor element 20 includes the connection terminals 24 electrically connected to the interconnects 30. The interconnects 30 are opposed to the connection terminals 24 and the pillar 110. The semiconductor device 10 includes the bonding layer pieces 70 bonding the connection terminals 24 and the interconnects 30. The bonding layer pieces 70 are each circular as viewed in the thickness-wise direction (z-direction) of the encapsulation resin 40.

In this structure, as described above in the operation of the present embodiment, stress applied from the encapsulation resin 40 (encapsulation part 60) to the bonding layer pieces 70 is decreased. Thus, cracks are less likely to be formed in the bonding layer pieces 70.
(1-8) The semiconductor device 10 includes the protective layer 80 arranged between the interconnect 30 and the bonding layer piece 70. The protective layer 80 is circular as viewed in the thickness-wise direction of the encapsulation resin 40.

In this structure, the shape of the bonding layer piece 70 arranged on the protective layer 80 tends to be dependent on the shape of the protective layer 80. The bonding layer piece 70 is readily shaped as a circle by shaping the protective layer 80 as a circle.
(1-9) The encapsulation resin 40 includes the substrate part 50 on which the semiconductor element 20 is mounted and the encapsulation part 60 encapsulating the semiconductor element 20. The interconnects 30 are formed on the substrate part 50. The pillar 110 extends through the substrate part 50 in the thickness-wise direction (z-direction) of the encapsulation resin 40. The substrate part 50 is thinner than the encapsulation part 60.

In this structure, the pillar 110 is arranged in the substrate part 50, having the smaller thickness. Thus, cracks are more likely to be formed in the substrate part 50 than in the encapsulation part 60. In the present embodiment, the corners of the pillar 110 include the curved portions 111 so that stress applied from the pillar 110 to the substrate part 50 is decreased. As a result, cracks are less likely to be formed in the substrate part 50.

### Second Embodiment

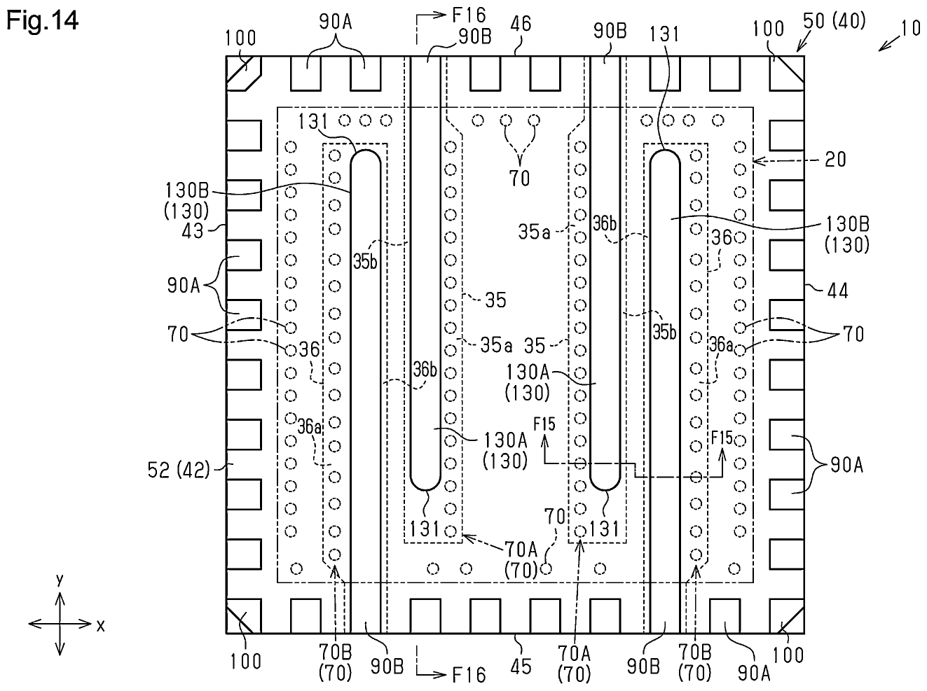

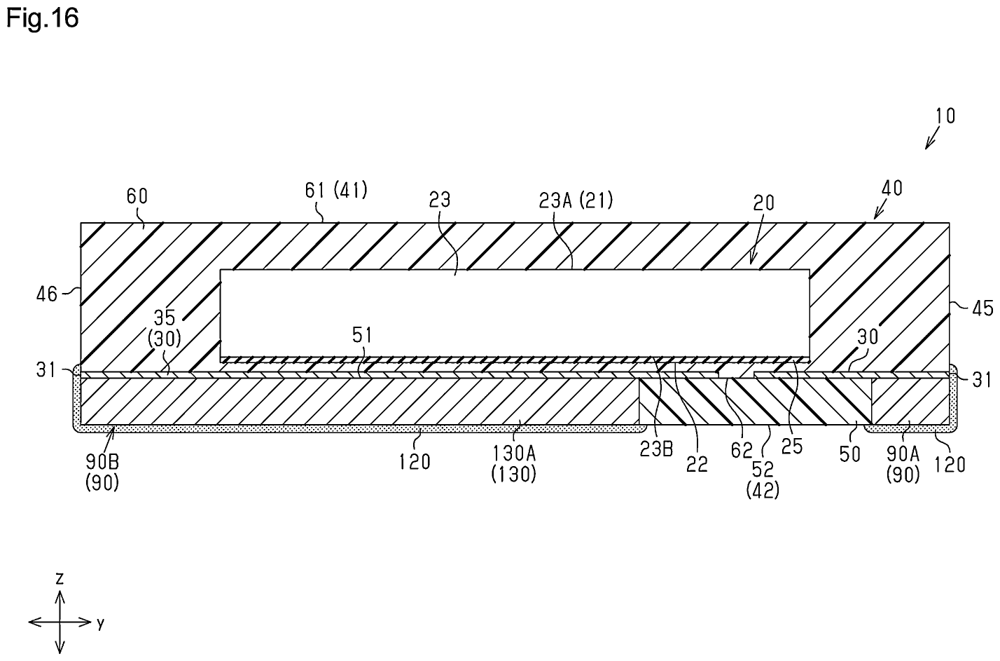

A second embodiment of a semiconductor device 10 will now be described with reference to FIGS. 14 and 16. The present embodiment mainly differs from the first embodiment in the structure of the external connection terminal 90. In the description hereafter, same reference numerals are given to those components that are the same as the corresponding components of the semiconductor device 10 in the first embodiment. Such components will not be described in detail. For the sake of convenience, FIG. 14 does not show the conductive film 120. Among the interconnects 30, FIG. 14 schematically shows interconnects 35 connected to pillars 130 and does not show the remaining interconnects 30.

FIG. 14 is a back view showing the present embodiment of a semiconductor device 10. As shown in FIG. 14, in the semiconductor device 10 of the present embodiment, in the same manner as the first embodiment, the external connection terminals 90 are arranged on an outermost peripheral portion of the encapsulation resin 40 as viewed in the z-direction. The external connection terminals 90 include two types of external connection terminal, namely, external connection terminals 90A and external connection terminals 90B. The external connection terminals 90A have the same structure as the external connection terminals 90 of the first embodiment. The external connection terminals 90B are formed of the pillars 130. In the present embodiment, the semiconductor device 10 includes four pillars 130. Therefore, four external connection terminals 90B are arranged. As described above, in the present embodiment, the external connection terminals 90 include terminals formed of the pillars 130.

The pillars 130 (external connection terminals 90B) are thermal pads that release heat from the semiconductor element 20 to the outside of the encapsulation resin 40. The pillars 130 extend in the y-direction. In the present embodiment, the y-direction corresponds to an “extension direction of pillar.” The pillars 130 may extend in the x-direction.

The multiple (four) pillars 130 include two first pillars 130A and two second pillars 130B. The first pillars 130A extend from the fourth resin side surface 46 toward the third resin side surface 45. The second pillars 130B extend from the third resin side surface 45 toward the fourth resin side surface 46. In the first pillars 130A, the fourth resin side surface 46 corresponds to a “first end in first direction extending along resin back surface.” The third resin side surface 45 corresponds to a “second end opposite to first end.” In the second pillars 130B, the third resin side surface 45 corresponds to a “first end in first direction extending along resin back surface.” The fourth resin side surface 46 corresponds to a “second end opposite to first end.” In the first pillars 130A and the second pillars 130B, the y-direction corresponds to a “first direction extending along resin back surface.” The x-direction corresponds to a “second direction.”

The two first pillars 130A are located closer to the center in the x-direction than the two second pillars 130B. The distance in the x-direction between the first pillar 130A and the second pillar 130B that are located close to each other is less than the distance in the x-direction between the two first pillars 130A.

The first pillars 130A extend from the fourth resin side surface 46 toward the third resin side surface 45 beyond the center of the resin back surface 42 in the y-direction. The second pillars 130B extend from the third resin side surface 45 toward the fourth resin side surface 46 beyond the center of the resin back surface 42 in the y-direction. In the present embodiment, the second pillars 130B are greater in length in the y-direction than the first pillars 130A. The lengths of the first pillars 130A and the second pillars 130B in the y-direction may be changed in any manner. In an example, the second pillars 130B and the first pillars 130A may be equal in length in the y-direction. The second pillars 130B may be smaller in length in the y-direction than the first pillars 130A.

In the present embodiment, the first pillars 130A are equal to the second pillars 130B in width-wise dimension. The width-wise dimension of each of the first pillars 130A and the second pillars 130B may be changed in any manner. In an example, the first pillars 130A may be greater in width-wise dimension than the second pillars 130B. The first pillars 130A may be smaller in width-wise dimension than the second pillars 130B.

As described above, the first pillars 130A and the second pillars 130B include the external connection terminals 90B. More specifically, the first pillars 130A and the second pillars 130B each include an external connection terminal that is electrically connected to a circuit board when the semiconductor device 10 is mounted on the circuit board.

The first pillar 130A includes a portion farthest from the fourth resin side surface 46, defining a distal surface and including a curved portion 131. The curved portion 131 of the first pillar 130A is arranged on the distal surface of the first pillar 130A and is convex toward the third resin side surface 45. The second pillar 130B includes a portion farthest from the third resin side surface 45, defining a distal surface and including the curved portion 131. The curved portion 131 of the second pillar 130B is arranged on the distal surface of the second pillar 130B and is convex toward the fourth resin side surface 46.

The curved portion 131 is formed on a portion of each of the pillars 130A and 130B that is in contact with the encapsulation resin 40. As viewed in the z-direction, the curved portion 131 is convex toward the encapsulation resin 40.

In the present embodiment, the curved portion 131 of the first pillar 130A is arranged on the entire distal surface of the first pillar 130A. The curved portion 131 of the second pillar 130B is arranged on the entire distal surface of the second pillar 130B. As viewed in the z-direction, the curved portion 131 is semicircular. That is, as viewed in the z-direction, the distal surface of the first pillar 130A and the distal surface of the second pillar 130B are semicircular. In the present embodiment, the radius of the semicircular curved portion 131 is greater than the diameter of the bonding layer piece 70. The radius of the curved portion 131 and the diameter of the bonding layer piece 70 may be changed in any manner. In an example, the radius of the curved portion 131 may be equal to the diameter of the bonding layer piece 70. The radius of the curved portion 131 may be smaller than the diameter of the bonding layer piece 70.

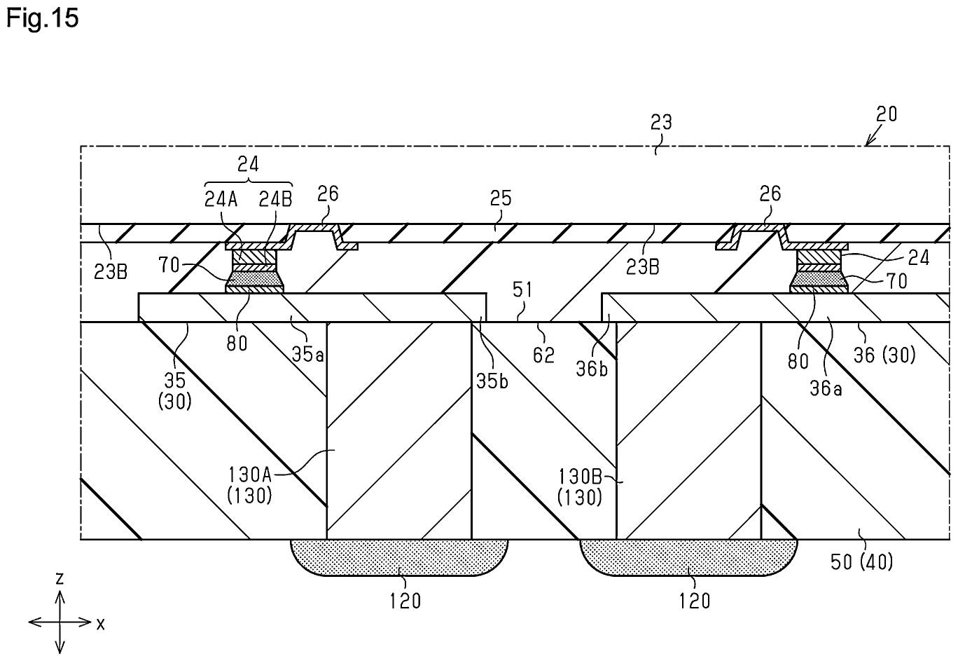

As shown in FIG. 15, the first pillar 130A and the second pillar 130B extend through the substrate part 50. The first pillar 130A and the second pillar 130B are equal in thickness to the substrate part 50.

As shown in FIG. 16, the first pillar 130A is exposed from the resin back surface 42 and the fourth resin side surface 46. A conductive film 120 is arranged on surfaces of the first pillar 130A exposed from the resin back surface 42 and the fourth resin side surface 46. The conductive film 120 is the same as the conductive film 120 of the first embodiment. Although not shown, the second pillar 130B is exposed from the resin back surface 42 and the third resin side surface 45. In the same manner as the first pillar 130A, a conductive film 120 is arranged on surfaces of the second pillar 130B exposed from the resin back surface 42 and the third resin side surface 45.

As shown in FIG. 14, each of the interconnects 35 indicated by broken lines is connected to the first pillar 130A and includes a portion overlapping the first pillar 130A as viewed in the z-direction. More specifically, as viewed in the z-direction, the interconnect 35 includes a portion overlapping the curved portion 131 of the first pillar 130A.

Interconnects 36 are indicated by broken lines and connected to the second pillars 130B. The interconnects 36 each include a portion overlapping the second pillar 130B as viewed in the z-direction. More specifically, as viewed in the z-direction, the interconnect 36 includes a portion overlapping the curved portion 131 of the second pillar 130B.

As shown in FIG. 14, the bonding layer pieces 70 are arranged next to each other in the y-direction at a side of the first pillar 130A opposite from the second pillar 130B and at a side of the second pillar 130B opposite from the first pillar 130A. That is, the bonding layer pieces 70 are not arranged between the first pillar 130A and the second pillar 130B that are located adjacent to each other in the x-direction. In the description hereafter, the bonding layer pieces 70 arranged next to each other in the y-direction at a side of the first pillar 130A opposite from the second pillar 130B are referred to as “first bonding layer pieces 70A.” The bonding layer pieces 70 arranged next to each other in the y-direction at a side of the second pillar 130B opposite from the first pillar 130A are referred to as “second bonding layer pieces 70B.”

As viewed in the z-direction, the interconnect 35 is arranged to be opposed to the first pillar 130A and the first bonding layer pieces 70A. The first pillar 130A is separated from the first bonding layer pieces 70A as viewed in the z-direction.

The first bonding layer pieces 70A are located toward the center of the resin back surface 42 in the x-direction from the first pillar 130A. Some of the first bonding layer pieces 70A are located toward the third resin side surface 45 beyond the first pillar 130A in the y-direction. The first bonding layer pieces 70A are arranged on the interconnect 35. The first bonding layer pieces 70A are arranged in the extension direction (y-direction) of the first pillars 130A.

As viewed in the z-direction, the interconnect 36 is arranged to be opposed to the second pillar 130B and the second bonding layer pieces 70B. The second pillar 130B is separated from the second bonding layer pieces 70B as viewed in the z-direction.

The second bonding layer pieces 70B are located toward an outer side of the resin back surface 42 from the second pillar 130B in the x-direction. All of the second bonding layer pieces 70B are arranged to overlap the second pillar 130B as viewed in the x-direction. The second bonding layer pieces 70B are arranged on the interconnect 36. The second bonding layer pieces 70B are arranged in the extension direction (y-direction) of the second pillars 130B.

As shown in FIGS. 14 and 15, each interconnect 35 includes extensions 35a and 35b extending out from opposite sides of the first pillar 130A in the x-direction. The extension 35a extends from the first pillar 130A toward the first bonding layer pieces 70A in the x-direction. The first bonding layer pieces 70A are arranged on the extension 35a. The extension 35b extends from the first pillar 130A toward the second pillar 130B in the x-direction. The extension 35a is greater than the extension 35b in dimension in the x-direction.

Each interconnect 36 includes extensions 36a and 36b extending out from opposite sides of the second pillar 130B in the x-direction. The extension 36a extends from the second pillar 130B toward the second bonding layer pieces 70B in the x-direction. The second bonding layer pieces 70B are arranged on the extension 36a. The extension 36b extends from the second pillar 130B toward the first pillar 130A in the x-direction. The extension 36a is greater than the extension 36b in dimension in the x-direction. Thus, the interconnects 35 and 36 are arranged so that the distance between the interconnect 35 and the interconnect 36 in the x-direction will not be excessively small.

### Advantages

The semiconductor device 10 of the present embodiment has the following advantages.
(2-1) The resin back surface 42 of the encapsulation resin 40 includes the first end and the second end opposite to the first end in the first direction (y-direction) extending along the resin back surface 42 as viewed in the thickness-wise direction (z-direction) of the encapsulation resin 40. The pillar 130 extends in the first direction from the basal end, that is, the first end of the resin back surface 42, toward the second end of the resin back surface 42 as viewed in the thickness-wise direction of the encapsulation resin 40. The curved portion 131 is arranged on the distal surface of the pillar 130 and is convex toward the second end.

Stress produced in the encapsulation resin 40 by changes in the temperature of the semiconductor device 10 is greater on the distal surface of the pillar 130 in the first direction (y-direction) than on the remaining portion of the pillar 130. Hence, cracks are more likely to be formed in a portion of the encapsulation resin 40 located adjacent to the distal surface of the pillar 130 in the first direction (y-direction).

In the present embodiment, the distal surface of the pillar 130 includes the curved portion 131 convex toward the second end. Thus, as compared to a pillar that does not include the curved portion 131, stress produced in the encapsulation resin 40 at the distal surface of the pillar 130 in the first direction (y-direction) is decreased. Thus, cracks are less likely to be formed in a portion of the encapsulation resin 40 located adjacent to the distal surface of the pillar 130 in the first direction (y-direction).
(2-2) The curved portion 131 is semicircular as viewed in the thickness-wise direction (z-direction) of the encapsulation resin 40.

This structure further decreases stress produced in the encapsulation resin 40 at the distal surface of the pillar 130 in the first direction (y-direction).
(2-3) The bonding layer pieces 70 are arranged in the extension direction of the pillar 130.

In this structure, the multiple bonding layer pieces 70 are bonded to the interconnect 35 that is bonded to the pillar 130. Thus, heat is released from the semiconductor element 20 to the outside of the semiconductor device 10 through the bonding layer pieces 70, the interconnect 35, and the pillar 130. The heat is efficiently released from the semiconductor element 20 to the outside of the semiconductor device 10.
(2-4) The pillars 130 include the first pillars 130A extending in the first direction (y-direction) and the second pillars 130B separated from the first pillars 130A in the second direction (x-direction) orthogonal to the first direction. The bonding layer pieces 70 are arranged next to each other in the first direction at the side of the first pillar 130A opposite from the second pillar 130B and at the side of the second pillar 130B opposite from the first pillar 130A.

In this structure, the bonding layer pieces 70A and 70B are not arranged between the first pillar 130A and the second pillar 130B in the x-direction. This avoids a situation in which the distance between the interconnect 35, which is connected to the first pillar 130A, and the interconnect 36, which is connected to the second pillar 130B, in the x-direction is excessively small between the first pillar 130A and the second pillar 130B in the x-direction. Thus, cracks are less likely to be formed in the encapsulation resin 40 (substrate part 50) between the first pillar 130A and the second pillar 130B in the x-direction.
(2-5) The first pillar 130A is exposed from the resin back surface 42 and the fourth resin side surface 46 of the encapsulation resin 40. The second pillar 130B is exposed from the resin back surface 42 and the third resin side surface 45 of the encapsulation resin 40.

In this structure, the area of the pillars 130A and 130B exposed from the encapsulation resin 40 is increased. Thus, heat is readily released from the semiconductor element 20 to the outside of the semiconductor device 10 through the pillars 130A and 130B.
(2-6) The semiconductor device 10 includes the conductive films 120 covering the portions of the first pillars 130A and the second pillars 130B exposed from the encapsulation resin 40.

In this structure, when the semiconductor device 10 is mounted on a circuit board, the conductive films 120 bond the first pillars 130A and the second pillars 130B to the circuit board. Thus, heat is readily transferred from the semiconductor element 20 to the circuit board through the first pillars 130A, the second pillars 130B, and the conductive films 120.

### Third Embodiment

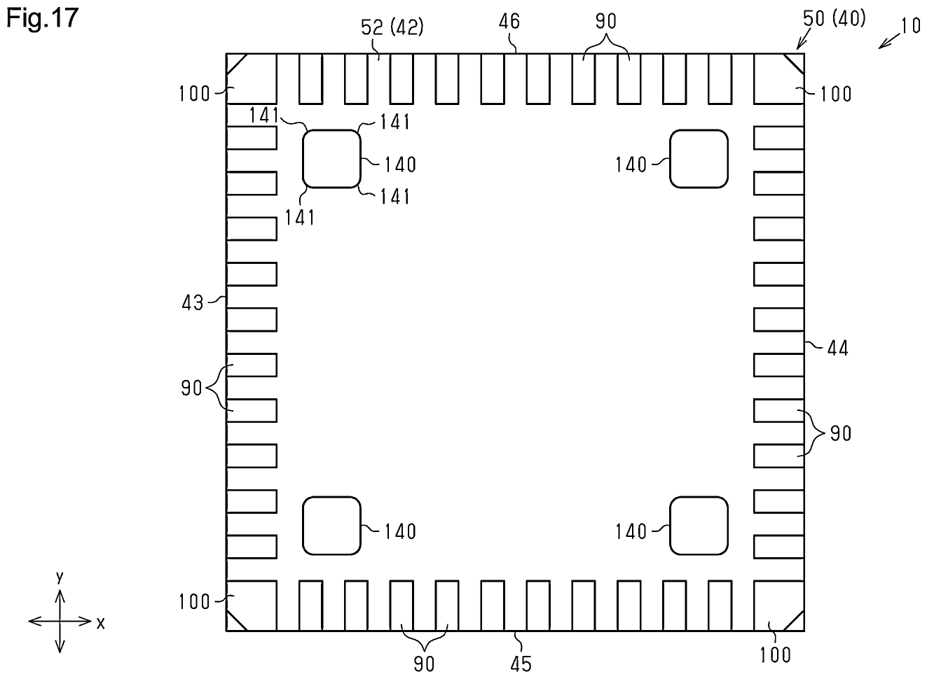

With reference to FIG. 17, a third embodiment of the semiconductor device 10 will now be described. The present embodiment mainly differs from the first embodiment in formation of the pillars. In the description hereafter, same reference numerals are given to those components that are the same as the corresponding components of the semiconductor device 10 in the first embodiment. Such components will not be described in detail.

As shown in FIG. 17, the semiconductor device 10 includes four pillars 140. The pillars 140 are arranged in correspondence with four corners of the resin back surface 42. The pillars 140 are located toward the center of the resin back surface 42 from the corner terminals 100. The pillars 140 are located toward the center of the resin back surface 42 from the external connection terminals 90. The pillars 140 are located toward the external connection terminals 90 from the center of the resin back surface 42. The pillars 140 are thermal pads that release heat from the semiconductor element 20 (refer to FIG. 2) to the outside of the encapsulation resin 40.

As viewed in the z-direction, the pillar 140 is quadrilateral (rectangular). The pillar 140 includes a curved portion 141 that relieves stress from the encapsulation resin 40. The curved portion 141 is formed on at least a part of the portion of the pillar 140 contacting the encapsulation resin 40. In the present embodiment, the curved portion 141 is arranged on four corners of the pillar 140. Thus, the pillar 140 is shaped as a polygon including corners that are rounded as the curved portions 141 as viewed in the z-direction. In the present embodiment, the pillar 140 is shaped as a quadrilateral including four corners that are rounded as the curved portions 141 as viewed in the z-direction. In the present embodiment, the curved portion 141 is arc-shaped. As described above, the curved portion 141 is convex toward the encapsulation resin 40 as viewed in the z-direction.

In the present embodiment, the pillar 140 has a dimension in the x-direction and a dimension in the y-direction that are equal to each other. The dimension of the pillar 140 in the x-direction (y-direction) may be equal to the long side of the external connection terminal 90. The dimensions of the pillar 140 in the x-direction and the y-direction may be changed in any manner. In an example, the dimension of the pillar 140 in the x-direction may be greater than the dimension of the pillar 140 in the y-direction. The dimension of the pillar 140 in the y-direction may be greater than the dimension of the pillar 140 in the x-direction. The dimension of the pillar 140 in the x-direction may be greater than the long side of the external connection terminal 90. The dimension of the pillar 140 in the x-direction may be smaller than the long side of the external connection terminal 90. The dimension of the pillar 140 in the y-direction may be greater than the long side of the external connection terminal 90. The dimension of the pillar 140 in the y-direction may be smaller than the long side of the external connection terminal 90. The structure described above obtains the same advantages as the first embodiment.

### Modified Examples

The embodiments described above may be modified as follows. The embodiments described above and the modified examples described below can be combined as long as the combined modifications remain technically consistent with each other.

In the first embodiment, the conductive film 120 may be omitted from the pillar 110. The conductive films 120 may be omitted from the corner terminals 100.

In the first embodiment, the pillar 110 may include a curved portion 111 instead of the slope 112. That is, the curved portions 111 may be arranged on the four corners of the pillar 110.

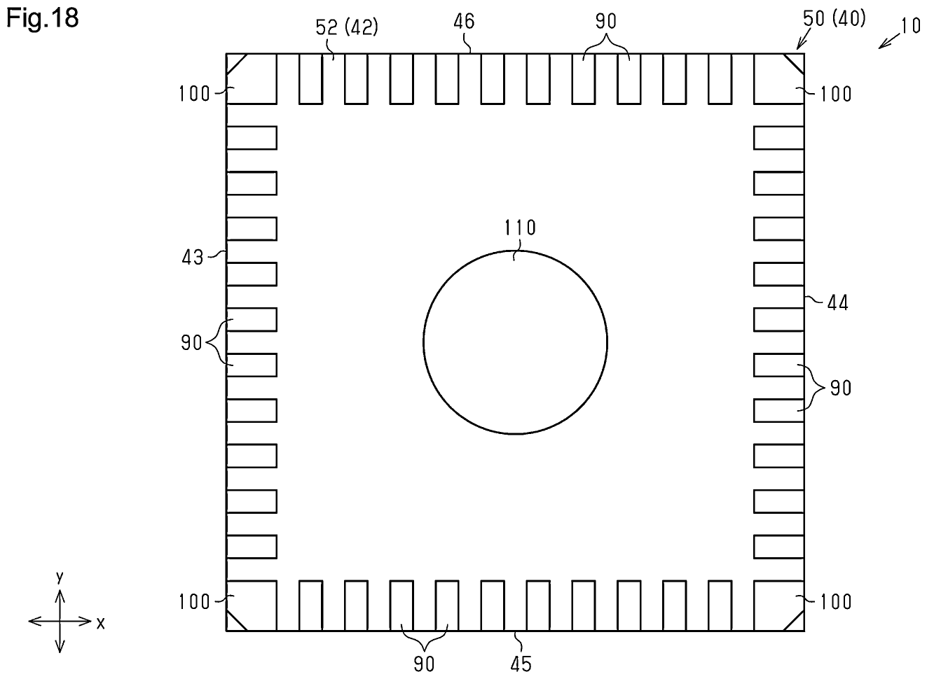

In the first embodiment, the shape of the pillar 110 as viewed in the z-direction may be changed in any manner. In an example, as shown in FIG. 18, the shape of the pillar 110 as viewed in the z-direction may be a circle. In the modified example shown in FIG. 18, the curved portion 111 is formed in the entire portion of the pillar 110 contacting the encapsulation resin 40.

In this structure, stress applied from the circumferential surface of the pillar 110 to the encapsulation resin 40 is likely to be uniform in the entire circumferential direction of the pillar 110. In other words, concentration of stress on the encapsulation resin 40 is limited. As a result, cracks are even less likely to be formed in the encapsulation resin 40.

In the second embodiment, the first pillar 130A does not necessarily have to be formed integrally with the external connection terminal 90. In this case, for example, the entirety of the first pillar 130A may be located inward from the external connection terminal 90 (90B) in the y-direction. The second pillar 130B does not necessarily have to be formed integrally with the external connection terminal 90. In this case, for example, the entirety of the second pillar 130B may be located inward from the external connection terminal 90 (90B) in the y-direction.

In the second embodiment, the distal surface of the first pillar 130A as viewed in the z-direction is semicircular. Alternatively, the distal surface of the first pillar 130A as viewed in the z-direction may include a corner that is rounded as the curved portion 131. In other words, the curved portion 131 may be arranged on a portion of the distal surface of the first pillar 130A as viewed in the z-direction. More specifically, as viewed in the z-direction, the distal surface of the first pillar 130A may include a flat surface extending in a direction (x-direction) orthogonal to the direction (y-direction) in which the first pillar 130A extends, and corners (curved portions) that are rounded at opposite sides of the flat surface in the x-direction. The shape of the distal surface of the second pillar 130B as viewed in the z-direction may be changed in the same manner.

In the second embodiment, the first pillar 130A may be arranged without being exposed from the fourth resin side surface 46 of the encapsulation resin 40. In this case, for example, the end of the first pillar 130A located close to the fourth resin side surface 46 may be semicircular and convex toward the fourth resin side surface 46. This limits formation of cracks in the encapsulation resin 40. The second pillar 130B may be arranged without being exposed from the third resin side surface 45 of the encapsulation resin 40. In this case, for example, the end of the second pillar 130B located close to the third resin side surface 45 may be semicircular and convex toward the third resin side surface 45. This limits formation of cracks in the encapsulation resin 40.

In the second embodiment, the number of first pillars 130A and the number of second pillars 130B may be changed in any manner.

In the second embodiment, either the first pillars 130A or the second pillars 130B may be omitted.

In the second embodiment, at least one of the first pillars 130A and the second pillars 130B does not necessarily have to be used as an external connection terminal. In this case, when the first pillars 130A are not used as an external connection terminal, the conductive film 120 does not necessarily have to be formed on a surface of the first pillars 130A exposed from the fourth resin side surface 46 and the resin back surface 42. Also, when the second pillars 130B are not used as an external connection terminal, the conductive film 120 does not necessarily have to be formed on a surface of the second pillars 130B exposed from the third resin side surface 45 and the resin back surface 42.

In the second embodiment, the bonding layer pieces 70 may be arranged between the first pillar 130A and the second pillar 130B.

The pillars 140 of the third embodiment may be added to one of the first embodiment and the second embodiment.

In the third embodiment, the shape of the pillar 140 as viewed in the z-direction is not limited to that shown in FIG. 17 and may be changed in any manner as long as the pillar 140 includes a curved portion that relieves stress from the encapsulation resin 40. In an example, the shape of the pillar 140 as viewed in the z-direction may be a circle.

In each embodiment, the diameter of the protective layer 80 may be changed in any manner. In an example, the diameter of the protective layer 80 may be equal to the diameter of the barrier layer 24B of the connection terminal 24. In this case, the bonding layer piece 70 may be cylindrical-rod-shaped or barrel-shaped.

In the embodiments, the shape of the protective layer 80 as viewed in the z-direction may differ from a circle. In an example, as viewed in the z-direction, the shape of the protective layer 80 may be a rectangle.

In the embodiments, the shape of the connection terminal 24 as viewed in the z-direction may differ from a circle. In an example, as viewed in the z-direction, the shape of the connection terminal 24 may be a rectangle.

In the embodiments, the shape of the bonding layer piece 70 as viewed in the z-direction may differ from a circle. In an example, as viewed in the z-direction, the shape of the bonding layer piece 70 may be a rectangle.

In the embodiments, at least one of the four corner terminals 100 may be omitted.

In each embodiment, the number of external connection terminals 90 may be changed in any manner. In an example, the external connection terminals 90 that correspond to the third resin side surface 45 and the fourth resin side surface 46 may be omitted.

In the embodiments, the external connection terminals 90 may be arranged without being exposed from the first to fourth resin side surfaces 43 to 46 of the encapsulation resin 40. That is, the external connection terminals 90 may be exposed from only the resin back surface 42.

In the embodiments, a curved portion may also be arranged on a corner of the external connection terminal 90. In this structure, the external connection terminal 90 corresponds to a “pillar.” This limits formation of cracks in the encapsulation resin 40 caused by the difference in thermal expansion coefficient between the external connection terminal 90 and the encapsulation resin 40.

In the embodiments, the pillars 110, 130, and 140 do not necessarily have to be connected to the interconnects 30. That is, the pillars 110, 130, and 140 do not necessarily have to be electrically connected to the semiconductor element 20.

In the embodiments, a curved portion may be arranged on a corner of the interconnect 30. This limits formation of cracks in the encapsulation resin 40 caused by the difference in thermal expansion coefficient between the interconnect 30 and the encapsulation resin 40.

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily have to be the vertical direction and does not necessarily have to fully conform to the vertical direction. In the structures according to the present disclosure, “upward” and “downward” in the z-direction as referred to in the present description are not limited to “upward” and “downward” in the vertical direction. In an example, the x-direction may conform to the vertical direction. In another example, the y-direction may conform to the vertical direction.

In this specification, “at least one of A and B” should be understood to mean “only A, only B, or both A and B.”

### Clauses

The technical aspects that are understood from the embodiment and the modified examples will be described below. To facilitate understanding without intention to limit, the reference signs of the elements in the embodiments are given to the corresponding elements in the clause with parentheses. The reference signs are used as examples to facilitate understanding, and the components in each clause are not limited to those components given with the reference signs.
1. A semiconductor device (10), including:
a semiconductor element (20) including an element front surface (21) and an element back surface (22);
an interconnect (30) electrically connected to the semiconductor element (20);
an encapsulation resin (40) including a resin front surface (41) facing in a same direction as the element front surface (21), a resin back surface (42) opposite to the resin front surface (41), and a resin side surface (43 to 46), the encapsulation resin (40) encapsulating the semiconductor element (20) and the interconnect (30); and
a pillar (110) electrically connected to the interconnect (30) and exposed from the resin back surface (42), in which
the pillar (110) includes a portion contacting the encapsulation resin (40) and at least partially including a curved portion (111) being convex toward the encapsulation resin (40) as viewed in a thickness-wise direction (z-direction) of the encapsulation resin (40).
2. The semiconductor device according to clause 1, in which the pillar (110) is shaped as a polygon including a corner that is rounded as the curved portion (111) as viewed in the thickness-wise direction (z-direction) of the encapsulation resin (40).
3. The semiconductor device according to clause 1, in which
the resin back surface (42) includes a first end and a second end opposite to the first end in a first direction (y-direction) extending along the resin back surface (42) as viewed in the thickness-wise direction (z-direction) of the encapsulation resin (40),
the pillar (130) extends from the first end of the resin back surface (42) toward the second end in the first direction as viewed in the thickness-wise direction (z-direction) of the encapsulation resin (40), and
the curved portion (131) is arranged on a distal surface of the pillar (130) and is convex toward the second end as viewed in the thickness-wise direction (z-direction) of the encapsulation resin (40).
4. The semiconductor device according to clause 3, in which
the curved portion (130) is arranged on the entire distal surface, and
the distal surface is semicircular as viewed in the thickness-wise direction (z-direction) of the encapsulation resin (40).
5. The semiconductor device according to any one of clauses 1 to 4, in which the interconnect (30) includes a portion overlapping the curved portion (111/131) as viewed in the thickness-wise direction (z-direction) of the encapsulation resin (40).
6. The semiconductor device according to any one of clauses 1 to 5, in which
the semiconductor element (20) includes a connection terminal (24) electrically connected to the interconnect (30), and
the connection terminal (24) is opposed to the interconnect (30),
the semiconductor device, further including:
a bonding layer piece (70) bonding the connection terminal (24) and the interconnect (30),
in which the bonding layer piece (70) is circular as viewed in the thickness-wise direction (z-direction) of the encapsulation resin (40).
7. The semiconductor device according to clause 6, further including:
a protective layer (80) arranged between the interconnect (30) and the bonding layer piece (70),
in which the protective layer (80) is circular as viewed in the thickness-wise direction (z-direction) of the encapsulation resin (40).
8. The semiconductor device according to clause 6 or 7, in which
the resin back surface (42) includes a first end and a second end opposite to the first end in a first direction (y-direction) extending along the resin back surface (42) as viewed in the thickness-wise direction (z-direction) of the encapsulation resin (40),
the pillar (130) extends from the first end of the resin back surface (42) toward the second end in the first direction as viewed in the thickness-wise direction (z-direction) of the encapsulation resin (40), and
the bonding layer piece (70) includes bonding layer pieces (70) arranged in an extension direction (y-direction) of the pillar (130).
9. The semiconductor device according to clause 8, in which
the pillar (130) includes
   a first pillar (130A) extending in the first direction, and
   a second pillar (130B) separated from the first pillar (130A) in a second direction (x-direction) that is orthogonal to the first direction (y-direction),
the bonding layer pieces (70A, 70B) are arranged next to each other in the first direction (y-direction) at a side of the first pillar (130A) opposite from the second pillar (130B) and at a side of the second pillar (130B) opposite from the first pillar (130A).
10. The semiconductor device according to any one of clauses 1 to 9, in which the pillar (110/130/140) includes a thermal pad.
11. The semiconductor device according to any one of clauses 1 to 10, further including:
external connection terminals (90) exposed from the resin back surface (42) and the resin side surface (43 to 46).
12. The semiconductor device according to clause 8 or 9, further including:
external connection terminals (90) exposed from the resin back surface (42) and the resin side surface (43 to 46),
in which the external connection terminals (90) include a terminal (90B) formed of the pillar (130).
13. The semiconductor device according to any one of clauses 1 to 12, further including:
a conductive film (120) covering a portion of the pillar (110/130/140) exposed from the encapsulation resin (40).
14. A semiconductor device, including:
a semiconductor element (20) including an element front surface (21) and an element back surface (22);
an interconnect (30) electrically connected to the semiconductor element (20);
an encapsulation resin (40) including a resin front surface (41) facing in a same direction as the element front surface (21), a resin back surface (42) opposite to the resin front surface (41), and a resin side surface (43 to 46), the encapsulation resin (40) encapsulating the semiconductor element (20) and the interconnect (30); and
a pillar (110) arranged to overlap the semiconductor element (20) as viewed in a thickness-wise direction (z-direction) of the encapsulation resin (40) and exposed from the resin back surface (42), in which
the pillar (110) includes a portion contacting the encapsulation resin (40) and at least partially including a curved portion (111) being convex toward the encapsulation resin (40) as viewed in the thickness-wise direction (z-direction) of the encapsulation resin (40).
15. The semiconductor device according to any one of clauses 1 to 14, in which
the encapsulation resin (40) includes
   a substrate part (50) on which the semiconductor element (20) is mounted, and
   an encapsulation part (60) encapsulating the semiconductor element (20), the interconnect (30) is mounted on the substrate part (50), and
the pillar (110) extends through the substrate part (50) in the thickness-wise direction (z-direction) of the encapsulation resin (40).
16. The semiconductor device according to clause 15, in which the substrate part (50) is smaller in thickness than the encapsulation part (60).
17. The semiconductor device according to clause 15, in which the substrate part (50) is smaller in thickness than the semiconductor element (20).
18. The semiconductor device according to clause 15, in which the substrate part (50) has a thickness of 40 μm or greater and 70 μm and less.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

1. A semiconductor device, comprising:
a semiconductor element including an element front surface and an element back surface;
an interconnect electrically connected to the semiconductor element;
an encapsulation resin including a resin front surface facing in a same direction as the element front surface, a resin back surface opposite to the resin front surface, and a resin side surface, the encapsulation resin encapsulating the semiconductor element and the interconnect; and
a pillar electrically connected to the interconnect and exposed from the resin back surface, wherein
the pillar includes a portion contacting the encapsulation resin and at least partially including a curved portion being convex toward the encapsulation resin as viewed in a thickness-wise direction of the encapsulation resin.

2. The semiconductor device according to claim 1, wherein the pillar is shaped as a polygon including a corner that is rounded as the curved portion as viewed in the thickness-wise direction of the encapsulation resin.

3. The semiconductor device according to claim 1, wherein
the resin back surface includes a first end and a second end opposite to the first end in a first direction extending along the resin back surface as viewed in the thickness-wise direction of the encapsulation resin,
the pillar extends from the first end toward the second end in the first direction as viewed in the thickness-wise direction of the encapsulation resin, and
the curved portion is arranged on a distal surface of the pillar and is convex toward the second end as viewed in the thickness-wise direction of the encapsulation resin.

4. The semiconductor device according to claim 3, wherein
the curved portion is arranged on the entire distal surface, and
the distal surface is semicircular as viewed in the thickness-wise direction of the encapsulation resin.

5. The semiconductor device according to claim 1, wherein the interconnect includes a portion overlapping the curved portion as viewed in the thickness-wise direction of the encapsulation resin.

6. The semiconductor device according to claim 1, wherein
the semiconductor element includes a connection terminal electrically connected to the interconnect, and
the connection terminal is opposed to the interconnect,
the semiconductor device, further comprising:
a bonding layer piece bonding the connection terminal and the interconnect,
wherein the bonding layer piece is circular as viewed in the thickness-wise direction of the encapsulation resin.

7. The semiconductor device according to claim 6, further comprising:
a protective layer arranged between the interconnect and the bonding layer piece,
wherein the protective layer is circular as viewed in the thickness-wise direction of the encapsulation resin.

8. The semiconductor device according to claim 6, wherein
the resin back surface includes a first end and a second end opposite to the first end in a first direction extending along the resin back surface as viewed in the thickness-wise direction of the encapsulation resin,
the pillar extends from the first end toward the second end in the first direction as viewed in the thickness-wise direction of the encapsulation resin, and
the bonding layer piece includes bonding layer pieces arranged in an extension direction of the pillar.

9. The semiconductor device according to claim 8, wherein
the pillar includes
a first pillar extending in the first direction, and
a second pillar separated from the first pillar in a second direction that is orthogonal to the first direction,
the bonding layer pieces are arranged next to each other in the first direction at a side of the first pillar opposite from the second pillar and at a side of the second pillar opposite from the first pillar.

10. The semiconductor device according to claim 1, wherein the pillar includes a thermal pad.

11. The semiconductor device according to claim 1, further comprising:
external connection terminals exposed from the resin back surface and the resin side surface.

12. The semiconductor device according to claim 8, further comprising:
external connection terminals exposed from the resin back surface and the resin side surface,
wherein the external connection terminals include a terminal formed of the pillar.

13. The semiconductor device according to claim 1, further comprising:
a conductive film covering a portion of the pillar exposed from the encapsulation resin.
